(19) United States
(12) Patent Application Publication
(10) Pub. No.: US 2025/0198709 A1
(43) Pub. Date: Jun. 19, 2025

(54) HEAT SINK

(71) Applicant: Furukawa Electric Co., Ltd., Tokyo (JP)

(72) Inventors: Yoshikatsu INAGAKI, Tokyo (JP); Yasuhiro UCHIMURA, Tokyo (JP); Hiroshi OKADA, Tokyo (JP)

(73) Assignee: Furukawa Electric Co., Ltd., Tokyo (JP)

(21) Appl. No.: 19/063,723

(22) Filed: Feb. 26, 2025

Related U.S. Application Data
(63) Continuation of application No. PCT/JP2023/030863, filed on Aug. 28, 2023.

(30) Foreign Application Priority Data
Aug. 30, 2022 (JP) 2022-136993

(51) Int. Cl. F28F 3/04; F28D 15/02

(52) U.S. Cl. CPC F28F 3/048; F28D 15/02

(57) ABSTRACT

An example heat sink includes a base portion having a first surface and a second surface facing the first surface, in which a heat-generating element is to be thermally connected to the second surface, and heat radiation fins provided upright on the first surface of the base portion, wherein the base portion and the heat radiation fins are integrally molded, and at least a part of a thermally conductive member is embedded in the heat sink.

### CROSS REFERENCE TO RELATED APPLICATIONS

The present application is a continuation application of International Patent Application No. PCT/JP2023/030863 filed on Aug. 28, 2023, which claims the benefit of Japanese Patent Application No. 2022-136993, filed on Aug. 30, 2022. The contents of these applications are incorporated herein by reference in their entirety.

### BACKGROUND

### Technical Field

The present disclosure relates to a heat sink including a base portion to which a heat-generating element is thermally connected and heat radiation fins, and particularly relates to a heat sink in which a thermally conductive member is embedded.

### Background

As a unit configured to cool heat-generating elements such as electronic components installed in a predetermined space, a heat sink in which heat radiation fins are provided on a base portion to which the heat-generating elements are thermally connected may be used. Furthermore, with increase in functionality of various devices, the heat generation amount of the heat-generating elements such as electronic components mounted on the devices is increasing, and it is increasingly important to improve the cooling performance of heat sinks.

In order to improve the cooling performance of a heat sink, it is necessary to improve fin efficiency of the heat radiation fins provided in the heat sink. Thus, heat pipes are provided in the base portion of the heat sink along a plane direction of the base portion, and heat from the heat-generating elements is transported to the entire region of the base portion provided with the heat radiation fins by the heat transport function of the heat pipes. The heat from the heat-generating elements is transported to the entire region of the base portion provided with the heat radiation fins by using the heat pipes, whereby the base portion is made thermally uniform to equalize the thermal load on the entire heat radiation fins and improve the fin efficiency of the heat radiation fins.

When providing the heat pipes in the base portion of a heat sink, it is necessary to improve thermal connectivity between the heat pipes and the heat radiation fins. Thus, there has been proposed a heat sink in which one end portions of a plurality of heat radiation fins and a container are integrally connected by insert-casting, by holding at least part of the container for a heat pipe and the one end portions of the heat radiation fins inside cavities so that the heat radiation fins are in an upright state with respect to the container, thereafter pouring a molten metal into the cavities, and solidifying the molten metal (Japanese Patent Laid-Open No. 11-083361).

In Japanese Patent Laid-Open No. 11-083361, the container for the heat pipe and the one end portions of the heat radiation fins are integrally wrapped by insert-casting by the cover that is the base portion formed by solidifying the molten metal to connect the heat radiation fins and the container in the state in which the heat radiation fins are upright with respect to the container, and thereby thermal connectivity between the heat radiation fins and the container for the heat pipe is improved.

On the other hand, since in Japanese Patent Laid-Open No. 11-083361, the heat radiation fins, the cover, and the container for the heat pipe that are separate bodies are integrated by insert-casting, contact resistance exists between the heat radiation fins and the cover, and there is a need for improvement in thermal connectivity between the heat radiation fins and the cover, that is, thermal conductivity from the cover to the heat radiation fins. Furthermore, in Japanese Patent Laid-Open No. 11-083361, there is a difficulty in improving the fin efficiency of the heat radiation fins by equalizing the thermal load in the entire heat radiation fins, in terms of the contact resistance of the heat radiation fins and the cover.

Further, since in mobile phone base stations, for example, the wireless communication volume has been increasingly growing in recent years, substrates on which many electronic components having relatively small heat generation amounts such as an antenna and amplifier and electronic components having large heat generation amounts such as FPGA (Field Programmable Gate Array) are arranged in a complicated manner are used. When many electronic components having various heat generation amounts that are mounted on the aforementioned substrate are thermally connected to a heat sink, it becomes difficult to keep thermal uniformity of the base portion of the heat sink, whereby the heat is hardly transferred uniformly to the heat radiation fins, and the fin efficiency of the heat radiation fins is reduced.

Furthermore, in order to prevent interference between the electronic components, the electronic components mounted on a substrate may be shielded by forming shield portions that are recessed parts corresponding to the positions and the shapes of the electronic components on a heat receiving surface of the base portion of the heat sink, and accommodating the electronic components in the shield portions. When the shield portions are provided on the heat receiving surface of the base portion of the heat sink, it is necessary to arrange the thermally conductive members to avoid the shield portions when the heat conducting members such as heat pipes are provided in the base member. Accordingly, when the shield portions are provided on the heat receiving surface of the base portion, the degree of freedom of arrangement of the thermally conductive members such as heat pipes is reduced, which makes it difficult to equalize the thermal load in the entire heat radiation fins to improve the fin efficiency of the heat radiation fins.

In Japanese Patent Laid-Open No. 2000-269676, there is proposed the heat sink having the configuration in which the base plate portion, a number of fins, and grooves are integrally molded by die cast, and heat pipes are embedded in the grooves formed on the surface on the opposite side to the fins of the base plate portion to thereby bring the heat pipes and the heat source into close contact with each other. In other words, in Japanese Patent Laid-Open No 2000-269676, the heat sink diffuses the heat generated by the heat source to the base plate portion, and radiates the heat from the fins, and as a result of the base plate portion and the fins being integrally formed as one component, the heat sink promotes diffusion of the heat from the heat-generating electronic components to the entire base plate portion, prevents local heat concentration, and makes it possible to efficiently radiate heat by the fins integrally formed with the base plate portion. However, in Japanese Patent Laid-Open No. 2000-269676, there is no mention of equalizing the thermal load in all the heat radiation fins to improve the fin efficiency.

### SUMMARY

The present disclosure is related to providing a heat sink excellent in thermal connectivity of a base portion and heat radiation fins, and excellent in degree of freedom of arrangement of thermally conductive members.

The gist of the configuration of the present disclosure is as follows.
{1} A heat sink including
a base portion having a first surface and a second surface facing the first surface, in which a heat-generating element is to be thermally connected to the second surface, and
heat radiation fins provided upright on the first surface of the base portion,
wherein the base portion and the heat radiation fins are integrally molded, and
at least a part of a thermally conductive member is embedded in the heat sink.
{2} The heat sink according to {1} including a block portion extended in an extending direction of the base portion, wherein the thermally conductive member is embedded in the block portion.
{3} The heat sink according to {1}, wherein the thermally conductive member is embedded in the base portion.
{4} The heat sink according to {2}, wherein the block portion is a protruding part of the first surface, which is protruded in a thickness direction of the base portion from the first surface of the base portion.
{5} The heat sink according to {2}, wherein the block portion is a protruding part of the second surface, which is protruded in a thickness direction of the base portion from the second surface of the base portion.
{6} The heat sink according to {2}, wherein the heat radiation fins each have a tip portion in a height direction of the heat radiation fins and a basal portion that is a rise start portion from the base portion, and the block portion is provided in a middle portion between the tip portion and the basal portion of each of the heat radiation fins.
{7} The heat sink according to any one of {1} to {6}, wherein the thermally conductive member has a heat receiving portion to be thermally connected to the heat-generating element.
{8} The heat sink according to any one of {1} to {6}, wherein the entire thermally conductive member is embedded in the heat sink.
{9} The heat sink according to {1}, wherein at least a partial region of the thermally conductive member has an exposed portion exposed from the second surface of the base portion, and the exposed portion is to be directly in contact with the heat-generating element.
{10} The heat sink according to {5}, wherein at least a partial region of the thermally conductive member has an exposed portion exposed from the protruding part of the second surface, and the exposed portion is to be directly in contact with the heat-generating element.
{11} The heat sink according to any one of {1} to {6}, wherein the thermally conductive member extends along an extending direction of the base portion.
{12} The heat sink according to {9} or {10}, wherein the thermally conductive member has a step portion that is bent in a thickness direction of the base portion, and the exposed portion is formed by the step portion.
{13} The heat sink according to {9} or {10}, wherein the thermally conductive member has a protrusion portion protruded in a thickness direction of the base portion, and the exposed portion is formed by the protrusion portion.
{14} The heat sink according to any one of {1} to {6}, wherein the thermally conductive member is a heat pipe or a vapor chamber.
{15} The heat sink according to any one of {1} to {6}, wherein the heat sink is a cast member, and the thermally conductive member is embedded in the heat sink by insert-casting.
{16} The heat sink according to {14}, wherein a sealed injection tube that is used to inject a working fluid into an inside of the heat pipe or the vapor chamber is provided in an inward direction from a peripheral edge portion of the heat sink.
{17} The heat sink according to {14}, wherein the heat pipe is a flat type heat pipe that is flattened.
{18} The heat sink according to {1}, including a block portion extended in an extending direction of the base portion, in which at least a part of the thermally conductive member is embedded in the block portion, wherein the block portion is a protruding part of the first surface, which is protruded in a thickness direction of the base portion from the first surface of the base portion, and on the block portion, the heat radiation fins that are lower than the heat radiation fins provided upright on the first surface other than the block portion are provided upright.
{19} The heat sink according to {1}, wherein a shape of the thermally conductive member in a longitudinal direction is a shape having a bent portion in plan view.
{20} The heat sink according to any one {1} to {6}, wherein the base portion has a first direction and a second direction orthogonal to the first direction, and the heat radiation fins each extend in an oblique direction with respect to the second direction of the base portion, and in an oblique direction with respect to the first direction.

In the aspect of the heat sink of the present disclosure, the heat sink includes the base portion to which the heat-generating element is to be thermally connected, the heat radiation fins that are heat exchange units, and the thermally conductive member. Furthermore, since in the aspect of the heat sink of the present disclosure, the base portion and the heat radiation fins are integrally molded, the base portion and the heat radiation fins are an integral member, and no boundary portion is formed between the base portion and the heat radiation fins.

Furthermore, since in the aspect of the heat sink of the present disclosure, at least the part of the thermally conductive member is embedded in the heat sink, an outer peripheral surface of at least the partial region of the thermally conductive member is not exposed from a surface of the base portion.

According to the aspect of the heat sink of the present disclosure, since the base portion having the first surface and the second surface facing the first surface, in which the heat-generating element is to be thermally connected to the second surface, and the heat radiation fins provided upright on the first surface of the base portion are included, and the base portion and the heat radiation fins are integrally molded, contact resistance between the base portion and the heat radiation fins is suppressed, and thermal connectivity between the base portion and the heat radiation fins is improved. Furthermore, according to the aspect of the heat sink of the present disclosure, since at least the part of the thermally conductive member is embedded in the heat sink, the heat sink is excellent in degree of freedom of arrangement of the thermally conductive member in the heat sink, and excellent in thermal connectivity of the thermally conductive member in the heat sink. Consequently, according to the aspect of the heat sink of the present disclosure, even when many electronic components having various heat generation amounts are thermally connected to the heat sink, thermal uniformity of the base portion of the heat sink can be maintained, and heat transfer from the base portion is uniformized in the entire heat radiation fins, whereby heat transfer from the base portion to the heat radiation fins is facilitated, and thermal load in the entire heat radiation fins is equalized. Accordingly, in the heat sink of the present disclosure, fin efficiency of the heat radiation fins is improved, and therefore heat radiation characteristics of the heat sink is improved.

According to the aspect of the heat sink of the present disclosure, the heat sink has the block portion extended in the extending direction of the base portion, and the thermally conductive member is embedded in the block portion, whereby it is possible to reliably secure a site for embedding the thermally conductive member.

According to the aspect of the heat sink of the present disclosure, since the thermally conductive member is embedded in the base portion, the entire base portion is smoothly made thermally uniform by the thermal conduction function of the thermally conductive member to uniformize the heat transfer from the base portion in the entire heat radiation fins, and thereby it is possible to further equalize the thermal load in the entire heat radiation fins to further improve the fin efficiency of the heat radiation fins.

According to the aspect of the heat sink of the present disclosure, since the block portion is the protruding part of the first surface, which is protruded in the thickness direction of the base portion from the first surface of the base portion, the entire base portion is reliably made thermally uniform by the thermal conduction function of the thermally conductive member, and heat transfer from the base portion is reliably uniformized in the entire heat radiation fins. Accordingly, it is possible to further equalize the thermal load in the entire heat radiation fins to further improve the fin efficiency of the heat radiation fins, and it is also possible to reliably improve the heat exchange function of the heat radiation fins.

According to the aspect of the heat sink of the present disclosure, since the block portion is provided in the middle portion between the tip portion and the basal portion of each of the heat radiation fins, the entire heat radiation fins are reliably made thermally uniform by the thermal conduction function of the thermally conductive member, and therefore, it is possible to reliably improve the fin efficiency of the heat radiation fins.

According to the aspect of the heat sink of the present disclosure, since the entire thermally conductive member is embedded in the heat sink, thermal connectivity of the thermally conductive member in the heat sink is further improved.

According to the aspect of the heat sink of the present disclosure, since at least the partial region of the thermally conductive member has an exposed portion exposed from the second surface of the base portion, and the exposed portion is directly in contact with the heat-generating element, thermal connectivity between the heat-generating element and the thermally conductive member is further improved, and therefore the heat radiation characteristics of the heat sink is further improved.

According to the aspect of the heat sink of the present disclosure, since the thermally conductive member is a heat pipe or a vapor chamber, the thermally conductive member includes heat transport characteristics, and therefore it is possible to further equalize the thermal load in the entire heat radiation fins to further improve the fin efficiency of the heat radiation fins.

According to the aspect of the heat sink of the present disclosure, since the heat sink is a cast member, and the thermally conductive member is embedded in the heat sink by insert-casting, the thermal connectivity of the thermally conductive member in the heat sink is further improved.

According to the aspect of the heat sink of the present disclosure, since the sealed injection tube of the heat pipe or the vapor chamber is provided in the inward direction from the peripheral edge portion of the heat sink, even when the heat sink is installed in an external environment exposed to wind, rain, and the like, corrosion of the heat pipe or the vapor chamber is prevented, and therefore, durability of the heat sink is improved.

According to the aspect of the heat sink of the present disclosure, since the heat pipe is a flat type heat pipe, it is possible to contribute to miniaturization of the heat sink.

According to the aspect of the heat sink of the present disclosure, since the heat sink has the block portion extended in the extending direction of the base portion, at least the part of the thermally conductive member is embedded in the block portion, the block portion is the protruding part of the first surface, which is protruded in the thickness direction of the base portion from the first surface of the base portion, and the heat radiation fins that are lower than the heat radiation fins provided upright on the first surface other than the block portion are provided upright on the block portion, heat that is not completely radiated in the heat radiation fins on the block portion where the thermally conductive member exists is transferred to the heat radiation fins provided upright on the site where the thermally conductive member does not exist, that is, the site other than the block portion, that is the heat radiation fins each having a large fin area, and therefore, it is possible to equalize the thermal load in the entire heat radiation fins to further improve the fin efficiency.

### BRIEF DESCRIPTION OF THE DRAWINGS

FIG. 1 is a perspective view explaining a heat sink according to a first embodiment of the present disclosure;

FIG. 2 is an explanatory view explaining a structure of the heat sink according to the first embodiment of the present disclosure;

FIG. 3 is an explanatory view explaining arrangement of thermally conductive members of the heat sink according to the first embodiment of the present disclosure from a plane direction;

FIG. 4 is a sectional side view taken along line A-A in FIG. 3 of the heat sink according to the first embodiment of the present disclosure;

FIG. 5 is an explanatory view of injection tubes used in heat pipes provided in the heat sink according to the first embodiment of the present disclosure;

FIG. 6 is a sectional side view explaining the injection tubes used for the heat pipes provided in the heat sink according to the first embodiment of the present disclosure;

FIG. 7 is an explanatory view showing an example of a use method of the heat sink according to the first embodiment of the present disclosure;

FIG. 8 is a sectional side view of a heat sink according to a second embodiment of the present disclosure;

FIG. 9 is a sectional side view of a heat sink according to a third embodiment of the present disclosure;

FIG. 10 is a sectional side view of a heat sink according to a fourth embodiment of the present disclosure;

FIG. 11 is a perspective view from a bottom surface direction explaining the heat sink according to the fourth embodiment of the present disclosure;

FIG. 12 is a sectional side view of a heat sink according to a fifth embodiment of the present disclosure;

FIG. 13 is an explanatory view of a heat pipe to be used in the heat sink according to the fifth embodiment of the present disclosure;

FIG. 14 is a sectional side view of a heat sink according to a sixth embodiment of the present disclosure;

FIG. 15 is a sectional side view of a heat sink according to a seventh embodiment of the present disclosure;

FIG. 16 is a perspective view from a bottom surface direction explaining the heat sink according to the seventh embodiment of the present disclosure;

FIG. 17 is an explanatory view of injection tubes used in heat pipes provided in a heat sink according to an eighth embodiment of the present disclosure;

FIG. 18 is an explanatory view of injection tubes used in heat pipes provided in a heat sink according to a ninth embodiment of the present disclosure;

FIG. 19 is a sectional side view explaining the injection tubes used in the heat pipes provided in the heat sink according to the ninth embodiment of the present disclosure.

FIG. 20 is an explanatory view of injection tubes used in heat pipes provided in a heat sink according to a tenth embodiment of the present disclosure;

FIG. 21 is a side view explaining the injection tubes used in the heat pipes provided in the heat sink according to the tenth embodiment of the present disclosure.

FIG. 22 is an explanatory view explaining arrangement of thermally conductive members of a heat sink according to an eleventh embodiment of the present disclosure from a plane direction;

FIG. 23 is an explanatory view explaining arrangement of thermally conductive members of a heat sink according to a twelfth embodiment of the present disclosure from a plane direction;

FIG. 24 is an explanatory view explaining arrangement of heat radiation fins of a heat sink according to a thirteenth embodiment of the present disclosure from a plane direction;

FIG. 25 is an explanatory view explaining arrangement of heat radiation fines of a heat sink according to a fourteenth embodiment of the present disclosure from a plane direction;

FIG. 26 is an explanatory view explaining arrangement of heat radiation fins of a heat sink according to a fifteenth embodiment of the present disclosure from a plane direction.

FIG. 27 is a sectional side view of a heat sink according to a sixteenth embodiment of the present disclosure;

FIG. 28 is a sectional side view of a heat sink according to another embodiment of the present disclosure; and

FIG. 29 is a sectional side view of a heat sink according to another embodiment of the present disclosure.

### DETAILED DESCRIPTION

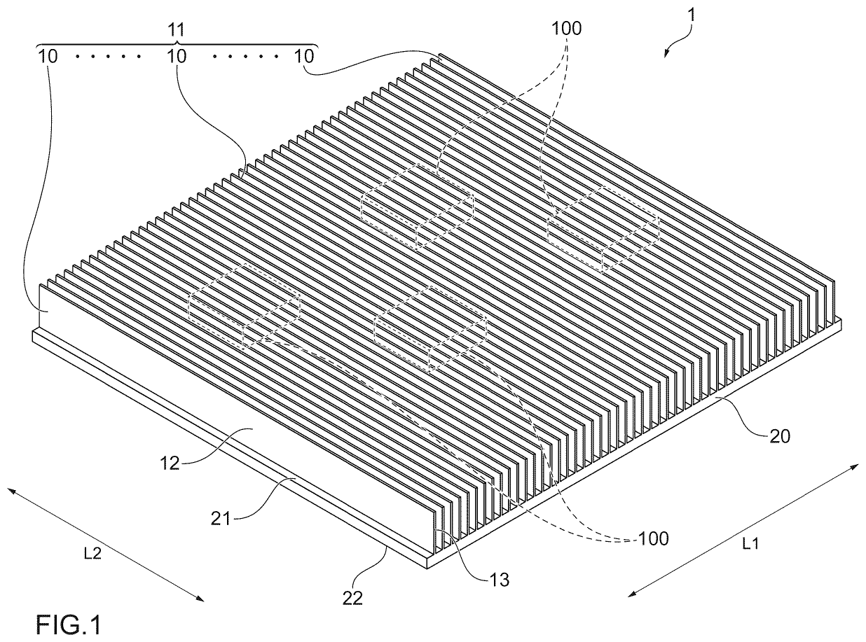

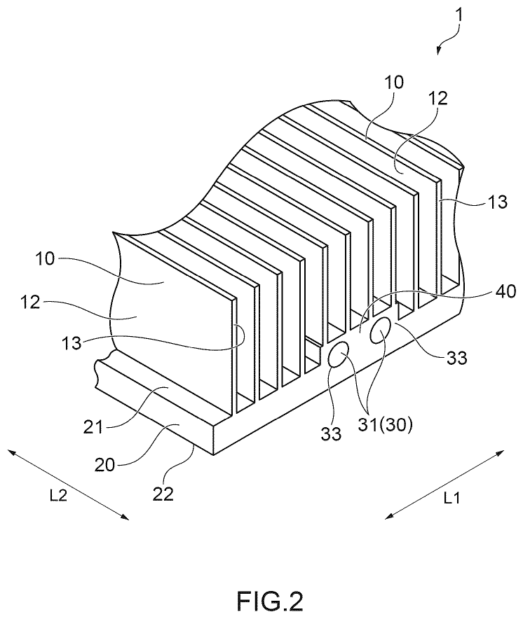

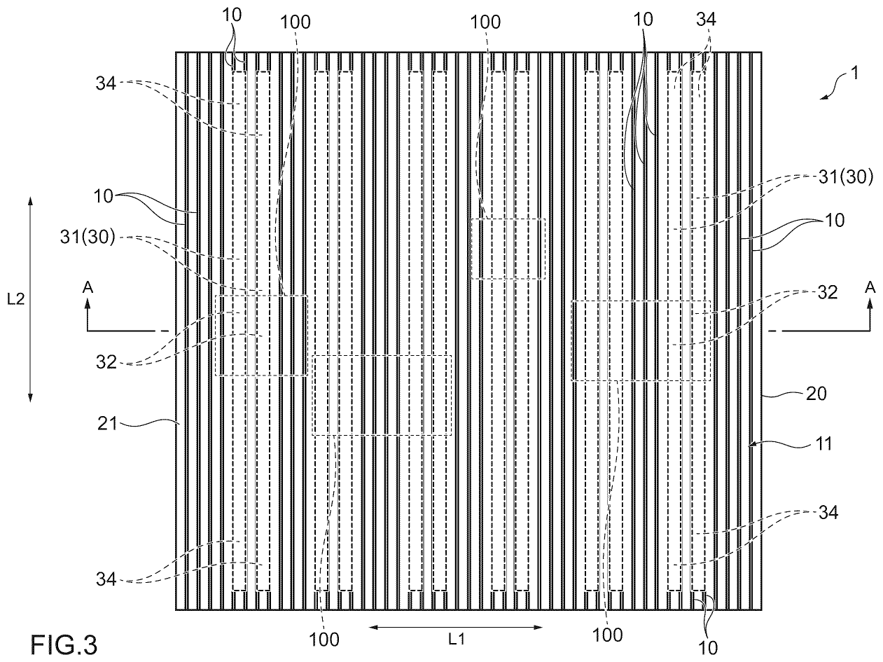

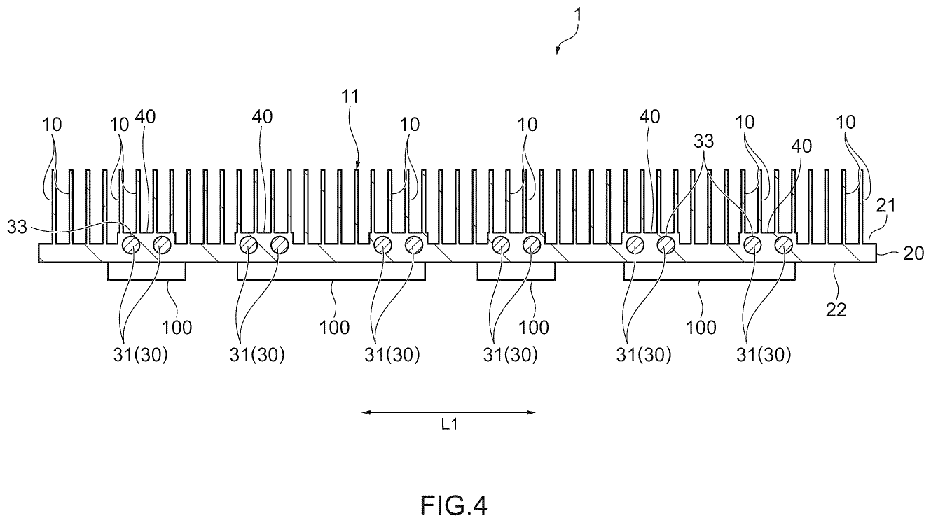

Hereinafter, a heat sink according to a first embodiment of the present disclosure will be described by using the drawings. FIG. 1 is a perspective view explaining the heat sink according to the first embodiment of the present disclosure. FIG. 2 is an explanatory view explaining a structure of the heat sink according to the first embodiment of the present disclosure. FIG. 3 is an explanatory view explaining arrangement of thermally conductive members of the heat sink according to the first embodiment of the present disclosure from a plane direction. FIG. 4 is a sectional side view taken along line A-A in FIG. 3 of the heat sink according to the first embodiment of the present disclosure.

As shown in FIGS. 1 and 2, a heat sink 1 according to the first embodiment includes a plate-shaped base portion 20, and a plurality of heat radiation fins 10, 10, 10 . . . provided on a front surface of the base portion 20. The base portion 20 has a first surface 21 and a second surface 22 facing the first surface 21. A heat-generating element 100 is thermally connected onto the second surface 22 of the base portion 20. On the first surface 21 of the base portion 20, the plurality of heat radiation fins 10, 10, 10 . . . are provided upright.

The base portion 20 is a plate-shaped site having a first direction L1 and a second direction L2 orthogonal to the first direction L1. While the shape of the base portion 20 is not particularly limited, in the heat sink 1 it has a quadrangular shape in plan view (state viewed from a position facing the heat radiation fin 10) for convenience of explanation. As a result of the heat-generating element 100 abutting on the second surface 22 of the base portion 20, the base portion 20 is thermally connected to the heat-generating element 100. Accordingly, the second surface 22 of the base portion 20 functions as a heat receiving surface.

The plurality of heat radiation fins 10, 10, 10 . . . that are plate-shaped are provided upright on the base portion 20. The heat radiation fin 10 is provided upright on the first surface 21 of the base portion 20 at a predetermined angle relative to an extending direction of the first surface 21. In the heat sink 1, the heat radiation fin 10 is provided upright in a substantially perpendicular direction to the extending direction of the first surface 21. Furthermore, each of the heat radiation fins 10 extends from one end to another end of the base portion 20 in the second direction L2. In the heat sink 1, for convenience of explanation, the heat radiation fin 10 extends substantially linearly from the one end to the other end of the base portion 20 in the second direction L2. Each of the heat radiation fins 10 extends in a substantially parallel direction to the second direction L2 of the base portion 20, and in a substantially orthogonal direction to the first direction L1. Furthermore, the heat radiation fin 10 has a substantially same height from the one end to the other end of the base portion 20 in the second direction L2.

The plurality of heat radiation fins 10, 10, 10 . . . are arranged in parallel at predetermined intervals on the first surface 21 of the base portion 20 to form a heat radiation fin group 11. In the heat sink 1, the plurality of heat radiation fins 10, 10 10 . . . are arranged in parallel from one end to another end of the base portion 20 in the first direction L1 to form the heat radiation fin group 11. Fin pitches of the plurality of heat radiation fins 10, 10, 10 . . . are not particularly limited, and in the heat sink 1, the plurality of heat radiation fins 10, 10, 10 . . . are arranged in parallel at substantially equal intervals throughout the entire heat radiation fin group 11.

In the heat sink 1, the base portion 20 and the plurality of heat radiation fins 10, 10, 10 . . . are integrally molded. In other words, it does not have an aspect in which the plurality of heat radiation fin 10, 10, 10 . . . are provided upright on the base portion 20 by combining together the base portion 20 and the plurality of heat radiation fins 10, 10, 10. . . . Accordingly, the base portion 20 and the plurality of heat radiation fins 10, 10, 10 . . . are an integral member, and between the base portion 20 and the plurality of heat radiation fins 10, 10, 10 . . . , boundary portions such as joint portions, bonded portions, or seams are not formed.

The heat radiation fins 10 are not provided on the second surface 22 of the base portion 20. Accordingly, the heat radiation fins 10 are provided on one surface of the base portion 20. The heat radiation fin 10 is a thin plate-shaped part, and has a main front surface 12 and a side surface 13. In the heat radiation fin 10, the main front surface 12 mainly contributes to heat radiation of the heat radiation fin 10. A width of the side surface 13 forms a thickness of the heat radiation fin 10.

Since the base portion 20 and the plurality of heat radiation fins 10, 10, 10 . . . are integrally molded, a material of the heat radiation fins 10 and a material of the base portion 20 are the same. The material of the heat radiation fins 10 and the base portion 20 are not particularly limited, and, for example, copper, copper alloy, aluminum, aluminum alloy and the like can be cited.

As shown in FIGS. 2, 3, and 4, at least part of a thermally conductive member 31 is embedded in the heat sink 1. The heat sink 1 has a block portion 40 that is a block-shaped site extended in the extending direction of the base portion 20, the thermally conductive member 31 is embedded in the block portion 40, and it is sufficient if at least one portion of the thermally conductive member 31 is embedded. In the heat sink 1, the block portion 40 extends from the one end to the other end of the base portion 20 in the second direction L2. Furthermore, for convenience of explanation, the block portion 40 extends substantially linearly from the one end to the other end of the base portion 20 in the second direction L2. Accordingly, the block portion 40 extends along the extending direction of the heat radiation fin 10.

In the heat sink 1, the block portion 40 is a protruding part of the first surface 21, which is protruded in a thickness direction of the base portion 20 from the first surface 21 of the base portion 20. The heat radiation fins 10 forming the heat radiation fin group 11 are also provided upright on the block portion 40. The block portion 40 is integrally molded with the base portion 20 and the plurality of heat radiation fins 10, 10, 10. . . . Accordingly, the block portion 40 is formed continuously to the first surface 21, and a boundary portion such as a joint portion, bonded portion, or seam is not formed between the block portion 40 and the first surface 21. Further, on the block portion 40, the heat radiation fins 10 that are lower than the heat radiation fins 10 provided upright on the first surface 21 other than the block portion 40 are provided upright.

Since a plurality of heat-generating elements 100, 100, 100 . . . are thermally connected to the second surface 22 of the base portion 20, a plurality of block portions 40 that are protruding parts of the first surface 21 are provided from the one end to the other end of the base portion 20 in the first direction L1. The plurality of block portions 40, 40, 40 . . . are positioned in parallel at predetermined intervals.

Correspondingly to the block portion 40 extending from the one end to the other end of the base portion 20 in the second direction L2, the thermally conductive member 31 extends from the one end to the other end of the base portion 20 in the second direction L2. Further, correspondingly to the block portion 40 substantially linearly extending from the one end to the other end of the base portion 20 in the second direction L2, the thermally conductive member 31 substantially linearly extends from the one end to the other end of the base portion 20 in the second direction L2. Accordingly, the thermally conductive member 31 extends along the extending direction of the base portion 20. Furthermore, the thermally conductive member 31 extends along the extending direction of the heat radiation fin 10. In other words, the thermally conductive member 31 extends in a substantially parallel direction to the extending direction of the heat radiation fin 10. Furthermore, the thermally conductive member 31 is provided at each of the plurality of block portions 40, 40, 40 . . . that are the protruding parts of the first surface 21. Accordingly, correspondingly to the plurality of block portions 40, 40, 40 . . . being positioned in parallel at predetermine intervals from the one end to the other end of the base portion 20 in the first direction L1, the plurality of thermally conductive members 31, 31, 31 . . . are arranged in parallel at predetermined intervals from the one end to the other end of the base portion 20 in the first direction L1. From the above, the plurality of thermally conductive members 31, 31, 31 . . . are arranged in parallel in a state where outer peripheral surfaces of the thermally conductive members 31 are faced to each other, along the first direction L1 of the base portion 20.

As shown in FIGS. 3 and 4, in the heat sink 1, the entire thermally conductive member 31 is embedded in the heat sink 1. Specifically, the entire thermally conductive member 31 is embedded in the block portion 40. Accordingly, an outer surface of the thermally conductive member 31 is not exposed from the block portion 40. In other words, the outer surface of the thermally conductive member 31 is not exposed from an outer surface of the base portion 20, or is not exposed from an outer surface of the heat sink 1.

The thermally conductive member 31 has a heat receiving portion 32 that is thermally connected to the heat-generating element 100. Furthermore, the thermally conductive member 31 has a site 34 other than the heat receiving portion 32. When the thermally conductive member 31 receives heat from the heat-generating element 100 in the heat receiving portion 32, the thermally conductive member 31 conducts the heat from the heat-generating element 100 from the heat receiving portion 32 to the site 34 other than the heat receiving portion 32 along the extending direction of the thermally conductive member 31. Note that when the thermally conductive member 31 is thermally connected to the plurality of heat-generating elements 100, 100, 100 . . . , a site that is thermally connected to the heat-generating element 100 that generates a large amount of heat among the plurality of heat-generating elements 100, 100, 100 . . . functions as the heat receiving portion 32.

In the heat sink 1, a heat pipe 30 that is a heat transport member is provided as the thermally conductive member 31. The heat pipe 30 has a container 33 that has a tubular shape and is sealed at one end and another end, a wick structure (not shown) having a capillary force and accommodated in the container 33, and a working fluid (not shown) such as water that is sealed in an internal space of the container 33. The container 33 is a tubular material in which the internal space is sealed. Furthermore, the internal space of the container 33 is decompressed by degassing. In the heat pipe 30, the heat receiving portion 32 functions as an evaporator portion, and the site 34 other than the heat receiving portion 32 functions as a condenser portion.

Although a shape in an orthogonal direction (radial direction) to a longitudinal direction of the container 33 is not particularly limited and may be a circular shape, elliptical shape, flat shape, rectangular shape, and the like, it is a circular shape in the heat sink 1.

The heat sink 1 is a cast member, and the thermally conductive member 31 (heat pipe 30) is embedded in the heat sink 1 by insert-casting. The heat pipe 30 is insert-casted integrally with the block portion 40 of the heat sink 1, and the heat pipe 30 is embedded and fixed into the block portion 40 that is the protruding part of the first surface 21. From the above, it is not necessary that the heat pipe 30 is fixed to the base portion 20 by solder joint. Accordingly, it is not necessary to additionally form a plated layer necessary for solder joints on the outer surface of the container 33 of the heat pipe 30.

A material of the container 33 of the heat pipe 30 may be the same as or different from the material of the base portion 20. As the material of the container 33 of the heat pipe 30, for example, copper, copper alloy, aluminum, aluminum alloy, titanium, titanium alloy, stainless steel and the like can be cited.

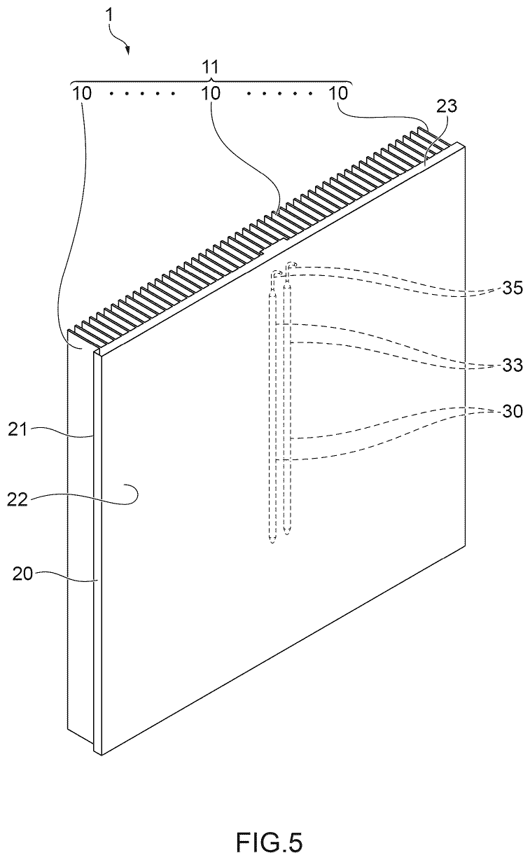

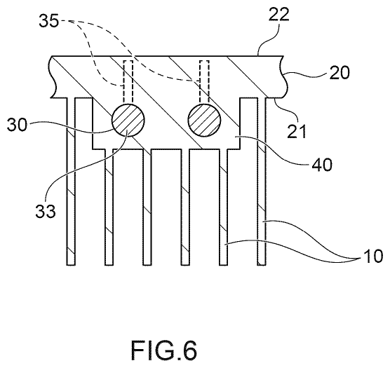

Next, an injection tube that is used to inject the working fluid into an insider of the heat pipe 30 will be described. FIG. 5 is an explanatory view of the injection tube used in the heat pipe provided in the heat sink according to the first embodiment of the present disclosure. FIG. 6 is a sectional side view explaining the injection tube sued in the heat pipe provided in the heat sink according to the first embodiment of the present disclosure.

The heat pipe 30 is produced by injecting the working fluid into the internal space of the container 33 from the injection tube that communicates with the internal space of the container 33 and extends from the container 33 after decompressing the internal space of the container 33, and sealing a predetermined portion of the injection tube after injecting the working fluid to seal the working fluid in the internal space of the container 33. As shown in FIGS. 5 and 6, a sealed injection tube 35 that is used to inject the working fluid into the inside of the heat pipe 30 is provided in an inward direction from a peripheral edge portion 23 of the heat sink 1. Accordingly, the sealed injection tube 35 is not in an aspect in which it is protruded in an outward direction from the peripheral edge portion 23 of the heat sink 1.

In the heat sink 1, the sealed injection tube 35 extends in a perpendicular direction to the extending direction of the heat pipe 30, and is thereby provided in the inward direction from the peripheral edge portion 23 of the heat sink 1. In the heat sink 1, the sealed injection tube 35 extends in a second surface 22 direction from the container 33 of the heat pipe 30. Note that in the heat sink 1, a dimension of the sealed injection tube 35 in the perpendicular direction is a dimension smaller than the thickness of the base portion 20. Accordingly, when the heat sink 1 is connected to a substrate on which the heat-generating element 100 that is an object to be cooled is mounted, the sealed injection tube 35 is positioned in an inside of the structure in which the substrate on which the heat-generating element 100 is mounted is connected to the heat sink 1, and is in an aspect in which the injection tube 35 is not exposed to an external environment of the structure. Note that a mounting position of the injection tube 35 is not particularly limited, and in the heat sink 1, the sealed injection tube 35 is provided at one end portion of the container 33. Furthermore, a shape of the sealed injection tube 35 that is provided at the one end portion of the container 33 has an L-shape.

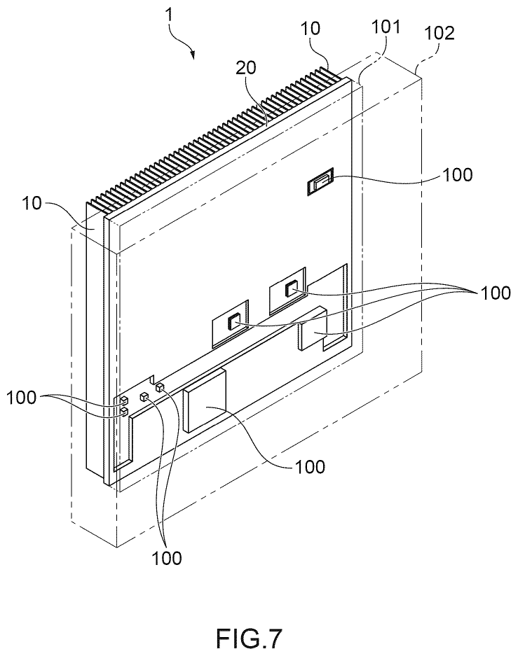

Next, an example of a use method of the heat sink 1 will be described. FIG. 7 is an explanatory view showing the example of the use method of the heat sink according to the first embodiment of the present disclosure.

As shown in FIG. 7, a substrate 101 is housed in a casing 102, and by thermally connecting many heat-generating elements 100, 100, 100 . . . having various heat generation amounts and mounted on the substrate 101 to the base portion 20 of the heat sink 1, the heat sink 1 can cool the many heat-generating elements 100, 100, 100. . . . In FIG. 7, the heat sink 1 is installed so that the base portion 20 of the heat sink 1 extends along a gravity direction and the heat radiation fins 10 extend along the gravity direction, correspondingly to the substrate 101 extending along the gravity direction. On the heat receiving surface of the base portion 20, shield portions that are recessed parts corresponding to positions and shapes of the many heat-generating elements 100, 100, 100 . . . are formed, and the heat-generating elements 100 are accommodated in the shield portions, whereby the heat-generating elements 100 mounted on the substrate 101 are electromagnetically shielded, and the heat-generating elements 100 are thermally connected to the heat receiving surface of the base portion 20.

When the many heat-generating elements 100, 100, 100 . . . are thermally connected to the heat receiving surface of the base portion 20, heat from the many heat-generating elements 100, 100, 100 . . . is transferred to the base portion 20. At this time, the many heat-generating elements 100, 100, 100 . . . have different heat generation amounts depending on the functions, and the many heat-generating elements 100, 100, 100 . . . are arranged in predetermined sites of the substrate 101 depending on the functions, so that when the heat from the many heat-generating elements 100, 100, 100 . . . is transferred to the base portion 20, the heat receiving amounts differ depending on the sites of the base portion 20. On the other hand, the heat pipe 30 embedded in the block portion 40 that is the protruding part of the first surface 21 has the heat receiving portion 32 that is thermally connected to the heat-generating element 100 via the base portion 20. Accordingly, the heat pipe 30 transports the heat from the heat-generating element 100 from the evaporator portion that is the heat receiving portion 32 to the condenser portion that is the site 34 other than the heat receiving portion 32 by the heat transport function of the heat pipe 30, and thereby the heat that is transferred from the heat-generating element 100 to the base portion 20 diffuses throughout the entire base portion 20. The heat that diffuses through the base portion 20 is transferred to the heat radiation fins 10 from the base portion 20, and the heat transferred to the heat radiation fins 10 is released to an outside of the heat sink 1 by the heat exchange action of the heat radiation fins 10. Note that cooling air that promotes the heat exchange action of the heat radiation fins 10 is generated from below to above in the gravity direction by natural convection, for example, without using a forced cooling unit such as a blower fan. Furthermore, as necessary, a forced cooling unit may be used to promote the heat exchange action of the heat radiation fins 10.

As the substrate 101 on which the many heat-generating elements 100, 100, 100 . . . having various heat generation amounts are mounted, a substrate and the like installed in a base station for a mobile phone are cited, for example. Furthermore, as the base station for a mobile phone, a base station attached to a tip portion of a steel tower is cited.

Next, an example of a manufacturing method of the heat sink 1 will be described. First, a mold corresponding to the shape of the heat sink 1 is prepared. Next, the containers 33 having the injection tubes 35, which are to be the heat pipes 30 are arranged in predetermined positions of the mold. At this time, the internal space of the container 33 is brought into a decompressed state by performing degassing in advance. Next, molten metal is press-fitted into the mold to integrate the heat sink 1 and the containers 33 each having the injection tube 35, and the containers 33 each having the injection tube 35 are embedded in the heat sink 1 by insert casting. Next, the working fluid such as water is injected into the internal spaces of the containers 33 via the injection tubes 35, and thereafter, the injection tubes 35 are sealed, whereby the heat sink 1 in which the heat pipes 30 are embedded can be obtained. Thereafter, desired shield portions are formed in the second surface 22 of the base portion 20, as necessary.

Since the heat sink 1 includes the base portion 20 having the first surface 21 and the second surface 22 facing the first surface 21, with the heat-generating element 100 thermally connected to the second surface 22, and the heat radiation fins 10 provided upright on the first surface 21 of the base portion 20, and the base portion 20 and the heat radiation fins 10 are integrally molded, the contact resistance between the base portion 20 and the heat radiation fins 10 is suppressed, and thermal connectivity between the base portion 20 and the heat radiation fins 10 is improved. Accordingly, even if many heat-generating elements 100 having various heat generation amounts are thermally connected to the base portion 20 of the heat sink 1, heat transfer from the base portion 20 to the heat radiation fins 10 is facilitated, in the heat sink 1. Furthermore, since in the heat sink 1, at least part of the thermally conductive members 31 (heat pipes 30, in the heat sink 1) is embedded in the block portions 40 that are the protruding part of the first surface 21, even when the shield portions are formed in the second surface 22 of the base portion 20, the heat sink 1 is excellent in degree of freedom of arrangement of the thermally conductive members 31 (heat pipes 30), and excellent in thermal connectivity of the thermally conductive members 31 (heat pipes 30) in the heat sink 1. Accordingly, in the heat sink 1, even when many heat-generating elements (for example, electronic components) 100 having various heat generation amounts are thermally connected to the base portion 20 of the heat sink 1, heat is diffused throughout the entire base portion 20 by the thermally conductive members 31 (heat pipes 30) and the entire base portion 20 is made thermally uniform, as a result of which, the thermal uniformity of the base portion 20 of the heat sink 1 can be maintained, and heat transfer from the base portion 20 is uniformized in the entire heat radiation fins 10. Accordingly, in the heat sink 1, thermal load in the entire heat radiation fins 10 is equalized to improve the fin efficiency of the heat radiation fins 10. From the above, even when the many heat-generating elements 100 having various heat generation amounts are thermally connected, heat radiation characteristics are also improved in the heat sink 1.

Further, since in the heat sink 1, the base portion 20 and the heat radiation fins 10 are integrally formed, even when the heat sink 1 is installed outdoors, it is possible to prevent rainwater, dust and the like from entering between the base portion 20 and the heat radiation fins 10, and therefore the heat sink 1 has excellent durability.

Since in particular, the heat sink 1 has the block portions 40 extended in the extending direction of the base portion 20, and the thermally conductive members 31 (heat pipes 30) are embedded in the block portions 40, it is possible to reliably secure the sites for embedding the thermally conductive members 31 (heat pipes 30).

Since in particular, in the heat sink 1, the block portion 40 is the protruding part of the first surface 21 protruded from the first surface 21 of the base portion 20 to the thickness direction of the base portion 20, the entire base portion 20 is reliably made thermally uniform by the heat conduction function of the thermally conductive members 31 (heat transport function of the heat pipes 30) and heat transfer from the base portion 20 is reliably uniformized in the entire heat radiation fins 10. Accordingly, in the heat sink 1, it is possible to further equalize the thermal load in the entire heat radiation fins 10 to further improve the fin efficiency of the heat radiation fins 10, and reliably improve the heat exchange function of the heat radiation fins 10.

Since in particular, in the heat sink 1, the entire thermally conductive members 31 (heat pipes 30) are embedded in the heat sink 1, the thermal connectivity of the thermally conductive members 31 (heat pipes 30) in the heat sink 1 is further improved.

Since in particular, in the heat sink 1, the thermally conductive members 31 include excellent heat transport characteristics as a result of the heat pipes 30 being used as the thermally conductive members 31, it is possible to further equalize the thermal load in the entire heat radiation fins 10 to further improve the fin efficiency of the heat radiation fins 10.

Since in particular, in the heat sink 1, the heat sink 1 is a cast member, and the thermally conductive members 31 (heat pipes 30) are embedded in the heat sink 1 by insert casting, the thermal connectivity of the thermally conductive members 31 (heat pipes 30) in the heat sink 1 is further improved.

Since in particular, in the heat sink 1, corrosion of the heat pipes 30 is prevented even when the heat sink 1 is installed in the external environment in which the heat sink 1 is exposed to wind, rain and the like as a result of the sealed injection tubes 35 of the heat pipes 30 being provided in the inward direction from the peripheral edge portion 23 of the heat sink 1, durability of the heat sink 1 is improved.

Since, in particular, in the heat sink 1, the heat pipes 30 are flat type heat pipes, it is possible to contribute to miniaturization of the heat sink 1.

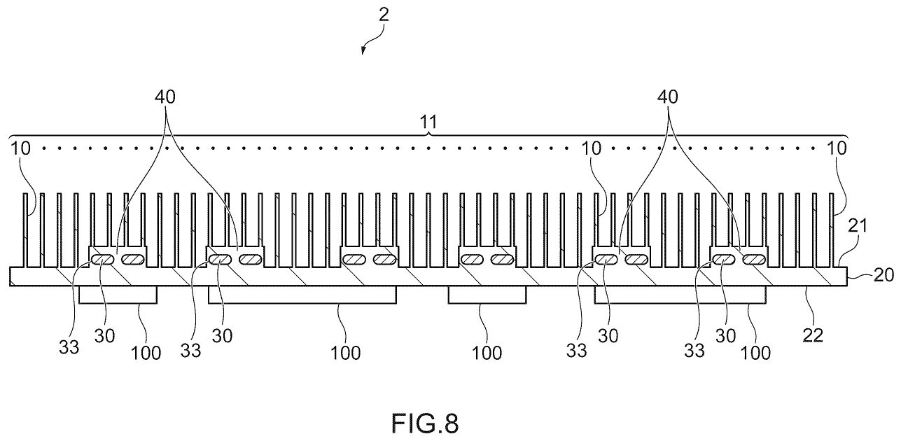

Next, a heat sink according to a second embodiment of the present disclosure will be described using the drawings. The heat sink according to the second embodiment has main components in common with the heat sink according to the first embodiment, and therefore the same components as those in the heat sink according to the first embodiment will be described using the same reference signs. Note that FIG. 8 is a sectional side view of the heat sink according to the second embodiment of the present disclosure.

In the heat sink 1 according to the first embodiment, the shape in the orthogonal direction (radial direction) to the longitudinal direction of the container 33 of the heat pipe 30 is a circular shape, but instead of this, as shown in FIG. 8, in a heat sink 2 according to the second embodiment, a shape in an orthogonal direction (radial direction) to a longitudinal direction of a container 33 of a heat pipe 30 is a flat shape. In the heat sink 2, the heat pipe 30 is a flat type heat pipe in which the container 33 is flattened.

As above, in the heat sink of the present disclosure, the shape in the radial direction of the container 33 of the heat pipe 30 is not particularly limited, and can be appropriately selected depending on conditions of use of the heat sink, and the like.

Since in the heat sink 2, a base portion 20 and heat radiation fins 10 are integrally molded, contact resistance between the base portion 20 and the heat radiation fins 10 is suppressed, and thermal connectivity between the base portion 20 and the heat radiation fins 10 is improved. Accordingly, in the heat sink 2, even when many heat-generating elements 100 having various heat generation amounts are thermally connected to the base portion 20 of the heat sink 2, heat transfer from the base portion 20 to the heat radiation fins 10 is facilitated. Further, since in the heat sink 2, at least part of the heat pipe 30 is embedded in a block portion 40 that is a protruding part of a first surface 21, even if shield portions are formed in a second surface 22 of the base portion 20, the heat sink 2 is also excellent in degree of freedom of arrangement of the heat pipes 30, and excellent in thermal connectivity of the heat pipes 30 in the heat sink 2. Accordingly, even if many heat-generating elements 100 having various heat generation amounts are thermally connected to the base portion 20 of the heat sink 2, heat is also diffused throughout the entire base portion 20 by the heat pipes 30, the entire base portion 20 is also made thermally uniform, and heat transfer from the base portion 20 is also uniformized in the entire heat radiation fins 10, in the heat sink 2. Accordingly, in the heat sink 2, thermal load in the entire heat radiation fins 10 is also equalized to improve fin efficiency of the heat radiation fins 10. From the above, in the heat sink 2, heat radiation characteristics are also improved even when many heat-generating elements 100 having various heat generation amounts are thermally connected.

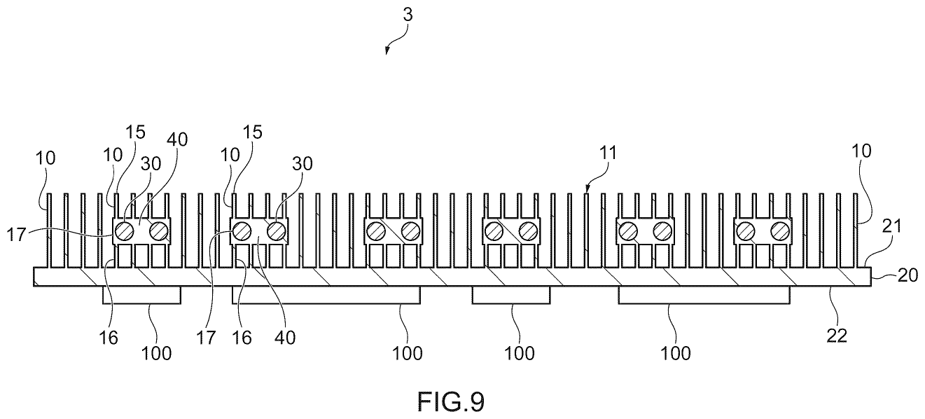

Next, a heat sink according to a third embodiment of the present disclosure will be described using the drawings. The heat sink according to the third embodiment has main components in common with the heat sinks according to the first and second embodiments, and therefore the same components as those in the heat sinks according to the first and second embodiments will be described using the same reference signs. Note that FIG. 9 is a sectional side view of the heat sink according to the third embodiment of the present disclosure.

In the heat sinks 1 and 2 according to the first and second embodiments, the block portion 40 in which the heat pipe 30 is embedded is the protruding part of the first surface 21, but instead of this, as shown in FIG. 9, in a heat sink 3 according to the third embodiment, a heat radiation fin 10 has a tip portion 15 in a height direction of the heat radiation fin 10, and a basal portion 16 that is a rise start portion from a base portion 20, and a block portion 40 in which a heat pipe 30 is embedded is provided on a middle portion 17 between the tip portion 15 and the basal portion 16 of the heat radiation fin 10. In the heat sink 3, respective block portions 40 are formed across a plurality of heat radiation fins 10, 10, 10 . . . .

In the heat sink 3, the block portion 40 in which the heat pipe 30 is embedded is provided in the middle portion 17 between the tip portion 15 and the basal portion 16 of the heat radiation fin 10, and thereby the entire heat radiation fins 10 are reliably made thermally uniform by a heat transport function of the heat pipes 30. In the heat sink 3, in the plurality of heat radiation fins 10, 10, 10 . . . , there exist the heat radiation fins 10 provided with the block portions 40, and the heat radiation fins 10 provided with no block portion 40. Among the plurality of heat radiation fins 10, 10, 10 . . . , the block portions 40 are provided in the heat radiation fins 10 that are difficult to make thermally uniform throughout the entire heat radiation fins 10 according to an arrangement situation of the heat-generating elements 100 and heat-generating amounts of the heat-generating elements 100.

Since in the heat sink 3, the base portion 20 and the heat radiation fins 10 are also integrally molded, contact resistance between the base portion 20 and the heat radiation fins 10 is also suppressed, and thermal connectivity between the base portion 20 and the heat radiation fins 10 is also improved. Furthermore, since the block portions 40 in which the heat pipes 30 are embedded are provided in the middle portions 17 of the heat radiation fins 10, even if shield portions are formed on a second surface 22 of the base portion 20, the heat sink 3 is excellent in degree of freedom of arrangement of the heat pipes 30, and excellent in thermal connectivity of the heat pipes 30 in the heat sink 3. Accordingly, even when many heat-generating elements 100 having various heat generation amounts are thermally connected to the base portion 20 of the heat sink 3, the entire heat radiation fins 10 are also reliably made thermally uniform by the heat pipes 30, in the heat sink 3, and therefore, it is also possible to equalize thermal load in the entire heat radiation fins 10 to improve the fin efficiency of the heat radiation fins 10. From the above, even when many heat-generating elements 100 having various heat generation amounts are thermally connected, the heat radiation characteristics are also improved in the heat sink 3.

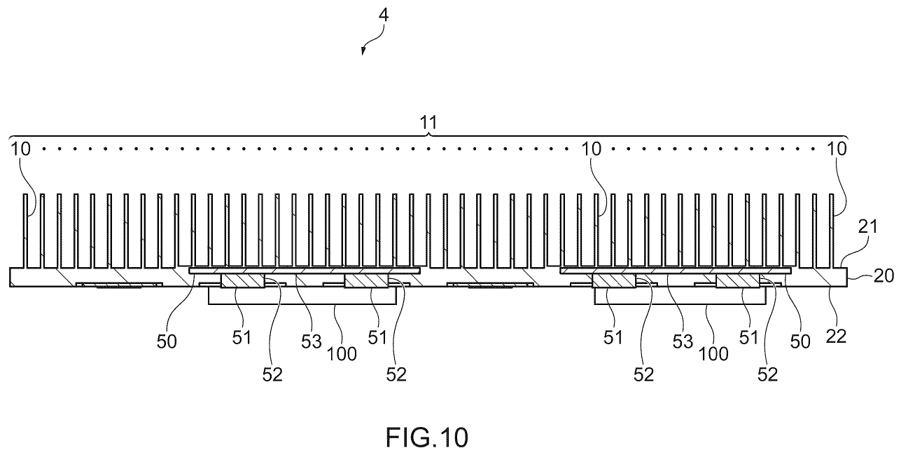

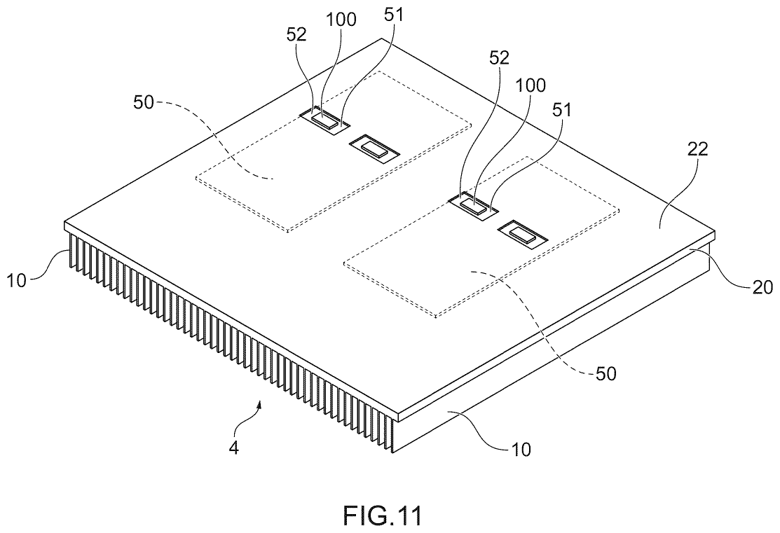

Next, a heat sink according to a fourth embodiment of the present disclosure will be described using the drawings. The heat sink according to the fourth embodiment has main components in common with the heat sinks according to the first to third embodiments, and therefore the same components as those in the heat sinks according to the first to third embodiments will be described using the same reference signs. Note that FIG. 10 is a sectional side view of the heat sink according to the fourth embodiment of the present disclosure. FIG. 11 is a perspective view from a bottom surface direction explaining the heat sink according to the fourth embodiment of the present disclosure.

In the heat sinks 1, 2, and 3 according to the first to third embodiments, the heat pipes 30 are used as the thermally conductive members, but instead of them, as shown in FIGS. 10 and 11, in a heat sink 4 according to the fourth embodiment, a vapor chamber 50 that is a heat transport member is used as a thermally conductive member.

The vapor chamber 50 has a planar type container 53 in which a peripheral edge portion of a stacked body having one plate-shaped body and another plate-shaped body is sealed, a wick structure (not shown) accommodated in the container 53 and having a capillary force, and a working fluid (not shown) such as water sealed in an internal space of the container 53. The container 53 having a thin plate shape is a member in which the internal space is hermetically sealed. Further, the internal space of the container 53 is decompressed by degassing. In the vapor chamber 50, a heat receiving portion functions as an evaporator portion, and a site other than the heat receiving portion functions as a condenser portion.

A material of the container 53 of the vapor chamber 50 may be the same as or different from a material of a base portion 20. As the material of the container 53 of the vapor chamber 50, for example, copper, copper alloy, aluminum, aluminum alloy, titanium, titanium alloy, stainless steel and the like can be cited.

Furthermore, in the heat sink 4, a sealed injection tube (not illustrated) that is used to inject a working fluid into an inside of the vapor chamber 50 is also provided in an inward direction from a peripheral edge portion of the heat sink 4. Furthermore, in the heat sink 4, the sealed injection tube also extends in a perpendicular direction to an extending direction of the vapor chamber 50, and therefore, is provided in the inward direction from the peripheral edge portion of the heat sink 4.

Furthermore, in the heat sinks 1, 2, and 3 according to the first to third embodiments, the block portions 40 in which the heat pipes 30 are embedded are provided, but instead of this, as shown in FIGS. 10 and 11, in the heat sink 4 according to the fourth embodiment, the vapor chamber 50 that is a thermally conductive member is embedded in the base portion 20. Accordingly, in the heat sink 4, a block portion for embedding the thermally conductive member is not formed. The heat sink 4 is a cast member, and the vapor chamber 50 is embedded in the heat sink 4 by insert casting. The vapor chamber 50 is integrally insert-casted with the base portion 20 of the heat sink 4, and the vapor chamber 50 is embedded and fixed into the base portion 20.

Furthermore, in the heat sinks 1, 2, and 3 according to the first to third embodiments, the entire heat pipes 30 that are the heat transport members are embedded in the block portions 40, but instead of this, as shown in FIGS. 10 and 11, the heat sink 4 according to the fourth embodiment has an aspect in which at least a partial region of the vapor chamber 50 has an exposed portion 51 exposed from a second surface 22 of the base portion 20, and the exposed portion 51 is directly in contact with the heat-generating element 100.

In the heat sink 4, the vapor chamber 50 has a protrusion portion 52 protruded in a thickness direction of the base portion 20, and the exposed portion 51 is formed by the protrusion portion 52. Specifically, a tip end that is a flat surface of the protrusion portion 52 is the exposed portion 51. In the heat sink 4, the protrusion portion 52 that is a protruding part is formed in the partial region of the container 53, and the partial region of the container 53 is exposed from the second surface 22 of the base portion 20. An inside of the protrusion portion 52 is a space and communicates with the internal space of the container 53. The number of protrusion portions 52 formed in the vapor chamber 50 may be one or two or more, and in the heat sink 4, a plurality (two) of protrusion portions 52 are provided.

Since in the heat sink 4, the base portion 20 and the heat radiation fins 10 are integrally molded, contact resistance between the base portion 20 and the heat radiation fins 10 is suppressed, and thermal connectivity between the base portion 20 and the heat radiation fins 10 is improved. Accordingly, even when many heat-generating elements 100 having various heat generation amounts are thermally connected to the base portion 20 of the heat sink 4, heat transfer from the base portion 20 to the heat radiation fins 10 is also facilitated, in the heat sink 4. Furthermore, since in the heat sink 4, the thin plate-shaped vapor chamber 50 is embedded in the base portion 20, even when a shield portion is formed in the second surface 22 of the base portion 20, the heat sink 4 is also excellent in degree of freedom of arrangement of the vapor chamber 50, and excellent in thermal connectivity of the vapor chamber 50 in the heat sink 4. Accordingly, even when many heat-generating elements 100 having various heat generation amounts are thermally connected to the base portion 20 of the heat sink 4, heat is also diffused throughout the entire base portion 20 by heat transport characteristics of the vapor chamber 50, the entire base portion 20 is also made thermally uniform, and heat transfer from the base portion 20 is also uniformized in the entire heat radiation fins 10, in the heat sink 4. Accordingly, in the heat sink 4, thermal load in the entire heat radiation fins 10 is also equalized to improve the fin efficiency of the heat radiation fins 10. From the above, in the heat sink 4, heat radiation characteristics are also improved even when many heat-generating elements 100 having various heat generation amounts are thermally connected.

Since in particular, in the heat sink 4, the vapor chamber 50 that is the thermally conductive member is embedded in the base portion 20, the entire base portion 20 is smoothly made thermally uniform by the heat transport function of the vapor chamber 50, and heat transfer from the base portion 20 is uniformized in the entire heat radiation fins 10, as a result of which, it is possible to further equalize the thermal load in the entire heat radiation fins 10 to further improve the fin efficiency of the heat radiation fins 10.

Since in particular, in the heat sink 4, the partial region of the vapor chamber 50 has the exposed portion 51 exposed from the second surface 22 of the base portion 20, and the exposed portion 51 can be directly in contact with the heat-generating element 100, the thermal connectivity between the heat-generating element 100 and the vapor chamber 50 is further improved, and therefore the heat radiation characteristics of the heat sink 4 is further improved.

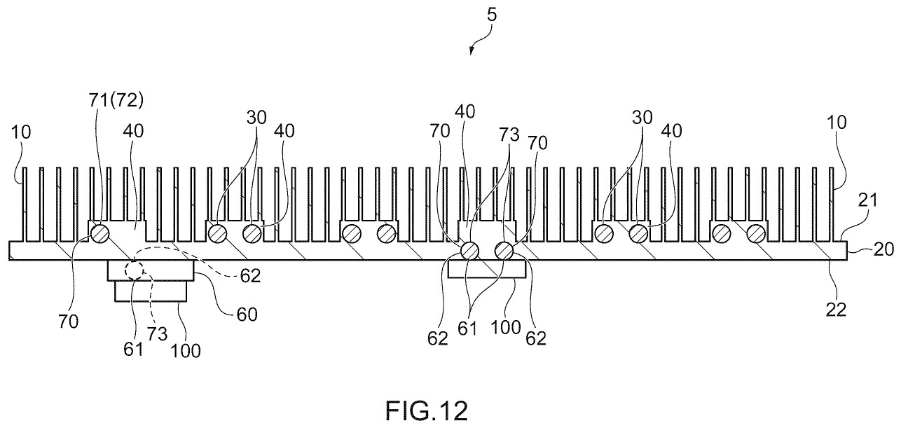

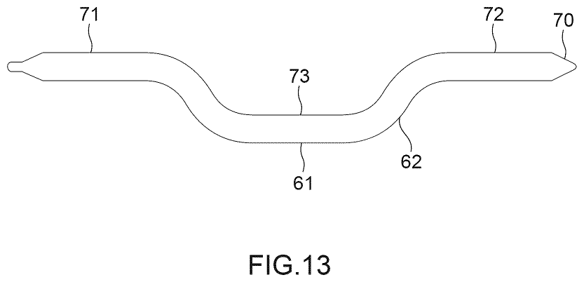

Next, a heat sink according to a fifth embodiment of the present disclosure will be described using the drawings. The heat sink according to the fifth embodiment has main components in common with the heat sinks according to the first to fourth embodiments, and therefore the same components as those in the heat sinks according to the first to fourth embodiments will be described using the same reference signs. Note that FIG. 12 is a sectional side view of the heat sink according to the fifth embodiment of the present disclosure. FIG. 13 is an explanatory view of a heat pipe used in the heat sink according to the fifth embodiment of the present disclosure.

In each of the heat sinks 1 and 2 according to the first and second embodiments described above, the heat pipe 30 extends substantially linearly from the one end to the other end of the base portion 20 in the second direction L2 correspondingly to the block portion 40 that is the protruding part of the first surface 21 extending substantially linearly from the one end to the other end of the base portion 20 in the second direction L2. Instead of this, as shown in FIGS. 12 and 13, in a heat sink 5 according to the fifth embodiment, a heat pipe 70 that is a thermally conductive member has a step portion 62 bent in a thickness direction of a base portion 20, and an exposed portion 61 of the heat pipe 70 which is exposed from a second surface 22 of the base portion 20 is formed by the step portion 62. In the heat sink 5, the step portion 62 is formed in a center portion 73 in a longitudinal direction of the heat pipe 70. No step portion is formed in one end portion 71 or another end portion 72 of the heat pipe 70, and the one end portion 71 and the other end portion 72 of the heat pipe 70 extend substantially linearly.

Furthermore, in the heat sink 5, in addition to a block portion 40 that is a protruding part of a first surface 21, a block portion 60 that is a protruding part of a second surface 22, which is protruded in the thickness direction of the base portion 20 from the second surface 22 of the base portion 20 is provided. In the heat pipe 70, the one end portion 71 and the other end portion 72 of the heat pipe 70 are embedded in the block portion 40 that is the protruding part of the first surface 21, and the step portion 62 positioned in the center portion 73 in the longitudinal direction of the heat pipe 70 is embedded in the block portion 60 that is the protruding part of the second surface 22. The heat pipe 70 extends from the block portion 40 that is the protruding part of the first surface 21 to the block portion 60 that is the protruding part of the second surface 22 as progresses from the one end portion 71 to the center portion 73 of the heat pipe 70. Further, as progresses from the center portion 73 to the other end portion 72 of the heat pipe 70, the heat pipe 70 extends from the block portion 60 that is the protruding part of the second surface 22 to the block portion 40 that is the protruding part of the first surface 21. Accordingly, a region of the center portion 73 of the heat pipe 70 has the exposed portion 61 that is exposed from the protruding part (block portion 60) of the second surface 22, and the exposed portion 61 is directly in contact with a heat-generating element 100.

A degree of a step of the step portion 62 can be appropriately selected according to a height of a site where the one end portion 71 and the other end portion 72 of the heat pipe 70 are embedded with respect to the second surface 22. Accordingly, the region of the center portion 73 of the heat pipe 70 may have the exposed portion 61 exposed from the second surface 22, and the exposed portion 61 may be directly in contact with the heat-generating element 100, without providing the block portion 60.

The heat sink 5 is provided with the heat pipe 70 in which the exposed portion 61 is formed by the step portion 62, and a heat pipe 30 that is embedded in the block portion 40 that is the protruding part of the first surface 21, with no exposed portion formed, and extends substantially linearly. In the heat sink 5, a shape in an orthogonal direction (radial direction) to the longitudinal direction, of the heat pipe 70 is a circular shape. Further, a shape in the orthogonal direction (radial direction) to the longitudinal direction of the heat pipe 30 is also a circular shape.

Since in the heat sink 5, the base portion 20 and heat radiation fins 10 are also integrally molded, contact resistance between the base portion 20 and the heat radiation fins 10 is suppressed, and thermal connectivity between the base portion 20 and the heat radiation fins 10 is improved. Furthermore, since in the heat sink 5, the one end portion 71 and the other end portion 72 of the heat pipe 70 are embedded in the block portion 40 that is the protruding part of the first surface 21, even when a shield portion is formed in the second surface 22 of the base portion 20, the heat sink 5 is also excellent in degree of freedom of arrangement of the heat pipes 70, and excellent in thermal connectivity of the heat pipes 30 and 70. Accordingly, even when many heat-generating elements 100 having various heat generation amounts are thermally connected to the base portion 20 of the heat sink 5, heat is also diffused throughout the entire base portion 20 by the heat pipes 30 and 70, the entire base portion 20 is also made thermally uniform, and the heat transfer from the base portion 20 is also uniformized in the entire heat radiation fins 10, in the heat sink 5. Accordingly, in the heat sink 5, thermal load in the entire heat radiation fins 10 is also equalized to improve the fin efficiency of the heat radiation fins 10.

Since in particular, in the heat sink 5, the partial region of the heat pipe 70 has the exposed portion 61 exposed from the second surface 22 of the base portion 20, and the exposed portion 61 can be directly in contact with the heat-generating element 100, the thermal connectivity between the heat-generating element 100 and the heat pipe 70 is further improved, and therefore, heat radiation characteristics of the heat sink 5 are further improved.

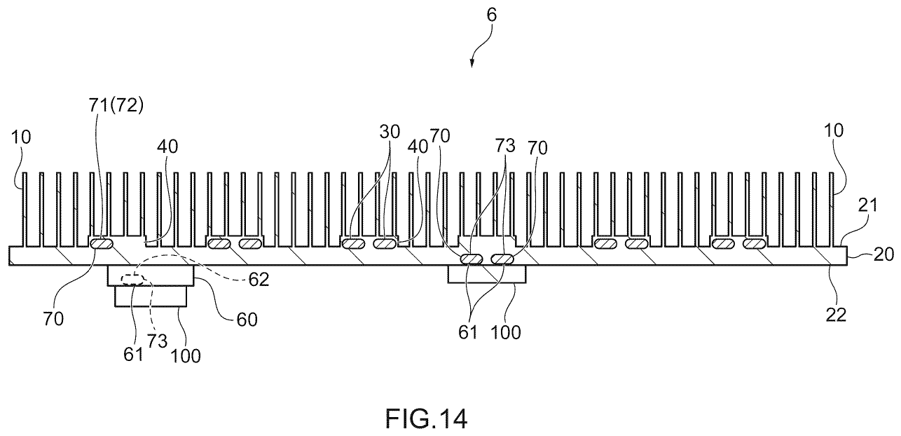

Next, a heat sink according to a sixth embodiment of the present disclosure will be described using the drawings. The heat sink according to the sixth embodiment has main components in common with the heat sinks according to the first to fifth embodiments, and therefore the same components as those in the heat sinks according to the first to fifth embodiments will be described using the same reference signs. Note that FIG. 14 is a sectional side view of the heat sink according to the sixth embodiment of the present disclosure.

In the heat sink 5 according to the fifth embodiment, the shapes of the heat pipes 30 and 70 in the orthogonal direction (radial direction) to the longitudinal direction are circular shapes, but instead of this, as shown in FIG. 14, in a heat sink 6 according to the sixth embodiment, a shape in a radial direction of a heat pipe 70 having a step portion 62 in a center portion 73 in the longitudinal direction is a flat shape, and a shape in the radial direction of the heat pipe 30 extending substantially linearly without having a step portion is a flat shape. Accordingly, both the heat pipes 30 and 70 are flat type heat pipes in which containers are flattened.

As above, in the heat sink of the present disclosure, the shape in the radial direction of the heat pipe 70 having the step portion 62 is not particularly limited, and can be appropriately selected according to conditions of use of the heat sink, and the like.

Since in the heat sink 6, a base portion 20 and heat radiation fins 10 are also integrally molded, contact resistance between the base portion 20 and the heat radiation fins 10 is suppressed, and thermal connectivity between the base portion 20 and the heat radiation fins 10 is improved. Furthermore, since in the heat sink 6, one end portion 71 and another end portion 72 of the heat pipe 70 are embedded in a block portion 40 that is a protruding part of a first surface 21, even if a shield portion is formed in a second surface 22 of the base portion 20, the heat sink 6 is also excellent in degree of freedom of arrangement of the heat pipe 70, and excellent in thermal connectivity of the heat pipes 30 and 70 in the heat sink 6. Accordingly, even when many heat-generating elements 100 having various heat generation amounts are thermally connected to the base portion 20 of the heat sink 6, heat is also diffused throughout the entire base portion 20 by the heat pipes 30 and 70, the entire base portion 20 is also made thermally uniform, and heat transfer from the base portion 20 is also uniformized in the entire heat radiation fins 10, in the heat sink 6. Accordingly, in the heat sink 6, thermal load in the entire heat radiation fins 10 is also equalized to improve fin efficiency of the heat radiation fins 10.

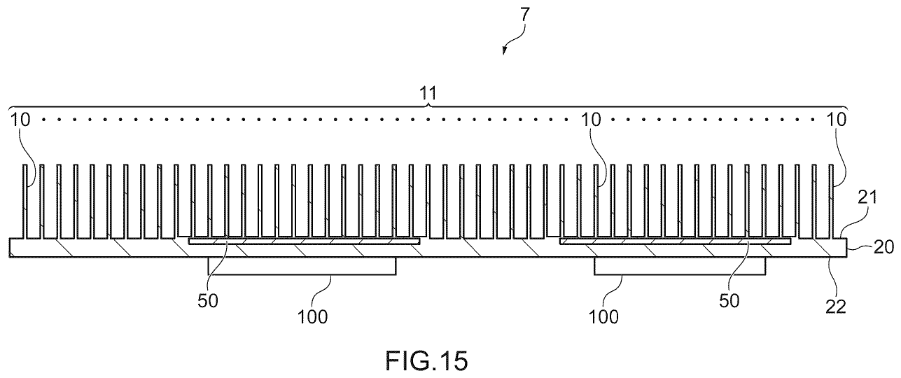

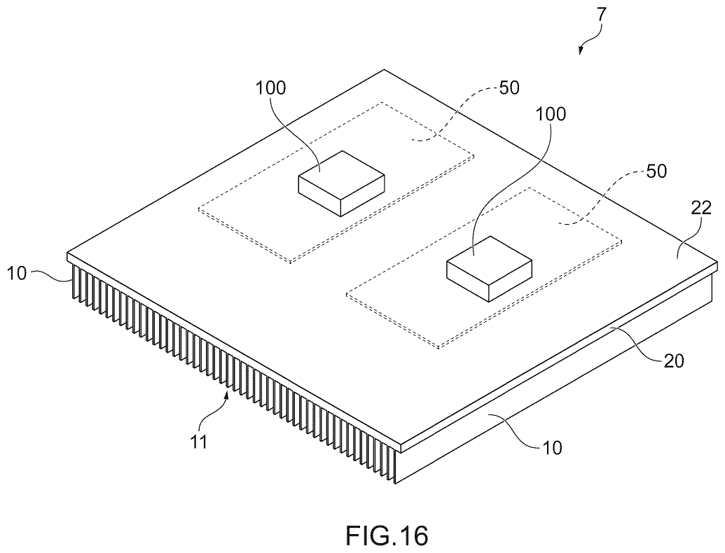

Next, a heat sink according to a seventh embodiment of the present disclosure will be described using the drawings. The heat sink according to the seventh embodiment has main components in common with the heat sinks according to the first to sixth embodiments, and therefore the same components as those in the heat sinks according to the first to sixth embodiments will be described using the same reference signs. Note that FIG. 15 is a sectional side view of the heat sink according to the seventh embodiment of the present disclosure. FIG. 16 is a perspective view from a bottom surface direction explaining the heat sink according to the seventh embodiment of the present disclosure.

In the heat sink 4 according to the fourth embodiment, the partial region of the vapor chamber 50 has the protrusion portion 52 protruded in the thickness direction of the base portion 20, and the exposed portion 51 is formed by the protrusion portion 52, whereas in a heat sink 7 according to the seventh embodiment, as shown in FIGS. 15 and 16, a vapor chamber 50 does not have a protrusion portion, and the entire vapor chamber 50 has a flat shape. Accordingly, in the heat sink 7, no exposed portion is formed in the vapor chamber 50.

In the heat sink 7, the entire vapor chamber 50 is embedded in a base portion 20. Accordingly, in the heat sink 7, a block portion for embedding a thermally conductive member is not formed. From the above, in the heat sink 7, the vapor chamber 50 is not in an aspect in which the vapor chamber 50 is directly in contact with a heat-generating element 100.

Since in the heat sink 7, the base portion 20 and heat radiation fins 10 are integrally molded, contact resistance between the base portion 20 and the heat radiation fins 10 is also suppressed, and thermal connectivity between the base portion 20 and the heat radiation fins 10 is also improved. Furthermore, since in the heat sink 7, the vapor chamber 50 having a thin plate shape is embedded in the base portion 20, even when a shield portion is formed in a second surface 22 of the base portion 20, the heat sink 7 is also excellent in degree of freedom of arrangement of the vapor chamber 50, and excellent in thermal connectivity of the vapor chamber 50 in the heat sink 7. Accordingly, in the heat sink 7, even when many heat-generating elements 100 having various heat generation amounts are thermally connected to the base portion 20 of the heat sink 7, heat is also diffused throughout the entire base portion 20 by the vapor chamber 50, the entire base portion 20 is also made thermally uniform, and heat transfer from the base portion 20 is also uniformized in the entire heat radiation fins 10. Accordingly, in the heat sink 7, thermal load in the entire heat radiation fins 10 is also uniformized to improve fin efficiency of the heat radiation fins 10.

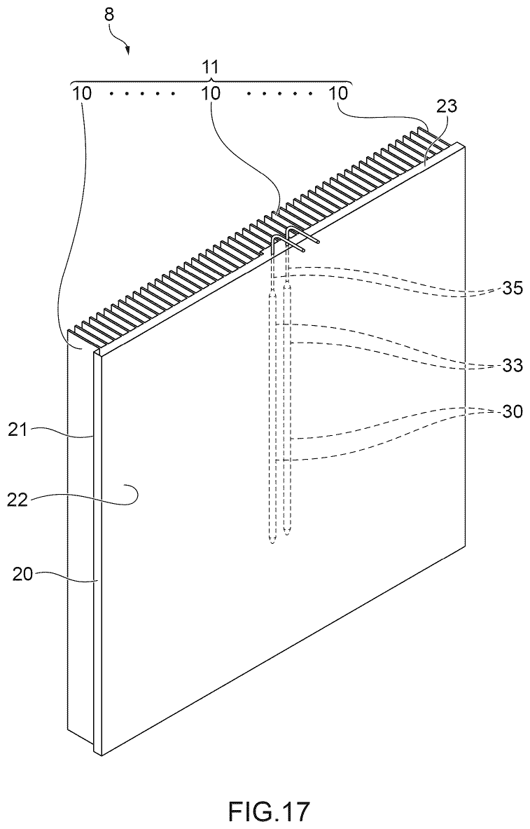

Next, a heat sink according to an eighth embodiment of the present disclosure will be described using the drawings. The heat sink according to the eighth embodiment has main components in common with the heat sinks according to the first to seventh embodiments, and therefore the same components as those in the heat sinks according to the first to seventh embodiments will be described using the same reference signs. Note that FIG. 17 is an explanatory view of an injection tube used in a heat pipe provided in the heat sink according to the eighth embodiment of the present disclosure.

In the heat sink 1 according to the first embodiment, the sealed injection tube 35 that is used to inject the working fluid to the inside of the heat pipe 30 is provided in the inward direction from the peripheral edge portion 23 of the heat sink 1, but instead of this, as shown in FIG. 17, in a heat sink 8 according to the eighth embodiment, a sealed injection tube 35 extends in an outward direction from a peripheral edge portion 23 of the heat sink 8. Accordingly, the sealed injection tube 35 is in an aspect in which the sealed injection tube 35 is protruded in the outward direction from the peripheral edge portion 23 of the heat sink 1.

Furthermore, in the heat sink 1 according to the first embodiment, a dimension of the sealed injection tube 35 in the perpendicular direction is a dimension smaller than the thickness of the base portion 20, but instead of this, as shown in FIG. 17, in the heat sink 8 according to the eighth embodiment, a dimension of the sealed injection tube 35 in the perpendicular direction is a dimension larger than a thickness of a base portion 20. In the heat sink 8, the sealed injection tube 35 extends in a direction of a second surface 22 of the base portion 20 from a container 33 of a heat pipe 30, and protrudes in a thickness direction of the base portion 20 from a position of the second surface 22.

Since in the heat sink 8, a tip portion of the sealed injection tube 35 is likely to be exposed to an external environment, corrosion resistance is given to an outer surface of the injection tube 35 as necessary. As a unit configured to give the corrosion resistance to the outer surface of the injection tube 35, for example, coating the outer surface of the injection tube 35 with an organic solvent having corrosion resistance or the like is cited. In this way, the sealed injection tube 35 may be in an aspect in which the sealed injection tube 35 is exposed to the external environment from the heat sink or may be in an aspect in which it is not exposed to the external environment.

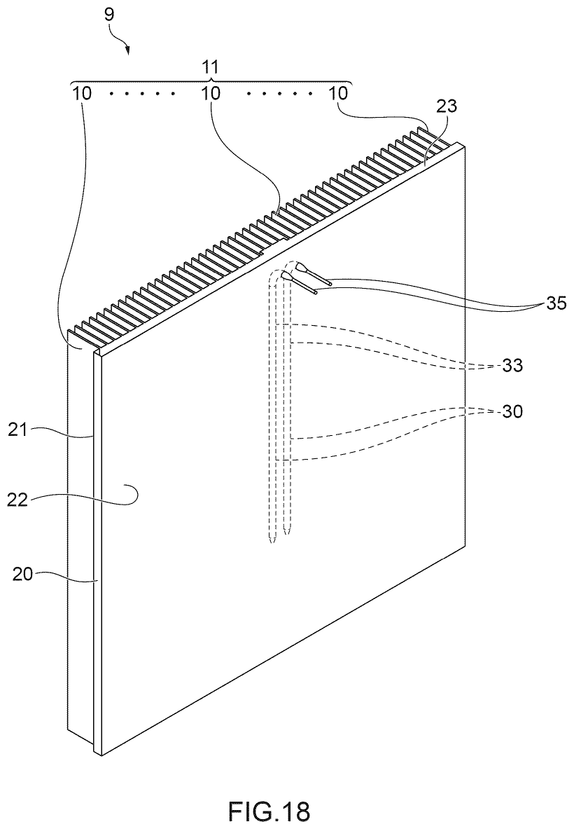

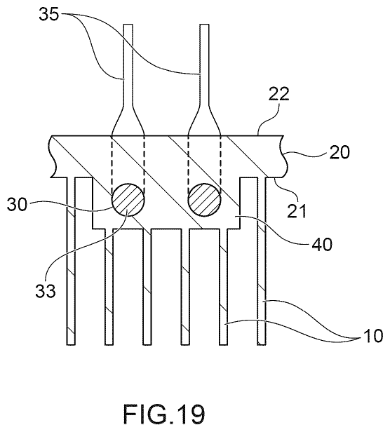

Next, a heat sink according to a ninth embodiment of the present disclosure will be described using the drawings. The heat sink according to the ninth embodiment has main components in common with the heat sinks according to the first to eighth embodiments, and therefore the same components as those in the heat sinks according to the first to eighth embodiments will be described using the same reference signs. Note that FIG. 18 is an explanatory view of an injection tube used in a heat pipe provided in the heat sink according to the ninth embodiment of the present disclosure. FIG. 19 is a sectional side view explaining the injection tube used in the heat pipe provided in the heat sink according to the ninth embodiment of the present disclosure.

In the heat sink 1 according to the first embodiment, the sealed injection tube 35 extends from the one end portion of the container 33 of the heat pipe 30 extending substantially linearly to the direction of the second surface 22, but instead of this, as shown in FIGS. 18 and 19, in a heat sink 9 according to the ninth embodiment, a container 33 of a heat pipe 30 has a center portion and another end portion that extend substantially linearly along an extending direction of a base portion 20, and one end portion extended in a thickness direction of the base portion 20, and an end surface of the one end portion of the container 33 is exposed from the second surface 22. A sealed injection tube 35 extends in a perpendicular direction to an extending direction of the second surface 22 from the end surface of the one end portion of the container 33, and the entire sealed injection tube 35 protrudes from the second surface 22.

As above, the sealed injection tube 35 may be in an aspect in which the sealed injection tube 35 is provided in an inward direction from a peripheral edge portion 23 of the heat sink 9, and the entire sealed injection tube 35 is positioned outside of the base portion 20.

Since in the heat sink 9, the base portion 20 and heat radiation fins 10 are also integrally molded, contact resistance between the base portion 20 and the heat radiation fins 10 is suppressed, and thermal connectivity between the base portion 20 and the heat radiation fins 10 is improved. Accordingly, even when many heat-generating elements 100 having various heat generation amounts are thermally connected to the base portion 20 of the heat sink 9, heat transfer from the base portion 20 to the heat radiation fins 10 is also facilitated in the heat sink 9. Furthermore, since in the heat sink 9, at least part of the heat pipe 30 is also embedded, even when a shield portion is formed in the second surface 22 of the base portion 20, the heat sink 9 is also excellent in degree of freedom of arrangement of heat pipes 30 and excellent in thermal connectivity of the heat pipe 30 in the heat sink 9. Accordingly, even when many heat-generating elements 100 having various heat generation amounts are thermally connected to the base portion 20 of the heat sink 9, heat is also diffused to the entire base portion 20 by the heat pipes 30, the entire base portion 20 is also made thermally uniform, and heat transfer from the base portion 20 is also uniformized in the entire heat radiation fins 10, in the heat sink 9. Accordingly, in the heat sink 9, thermal load in the entire heat radiation fins 10 is equalized to improve fin efficiency of the heat radiation fins 10. From the above, even when many heat-generating elements 100 having various heat generation amounts are thermally connected, heat radiation characteristics are also improved in the heat sink 9.

Furthermore, since n the heat sink 9, the sealed injection tube 35 of the heat pipe 30 is provided in an inward direction from the peripheral edge portion 23 of the heat sink 9, the sealed injection tube 35 is positioned in an inside of a structure in which a substrate on which the heat-generating element 100 is mounted is connected to the heat sink 9. Accordingly, the sealed injection tube 35 is in an aspect in which the sealed injection tube 35 is not exposed to an external environment of the structure. From the above, even when the heat sink 9 is installed in the external environment exposed to wind, rain and the like, corrosion of the container 33 of the heat pipe 30 and the sealed injection tube 35 is prevented, and therefore, durability of the heat sink 9 is improved.

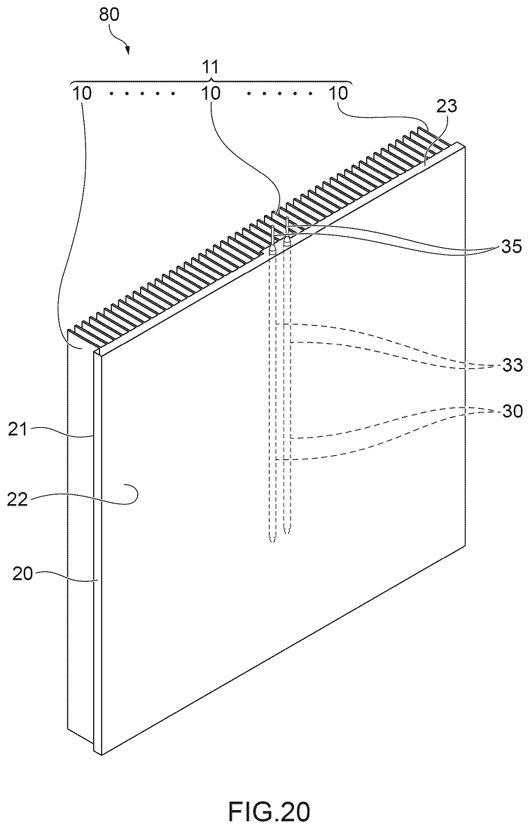

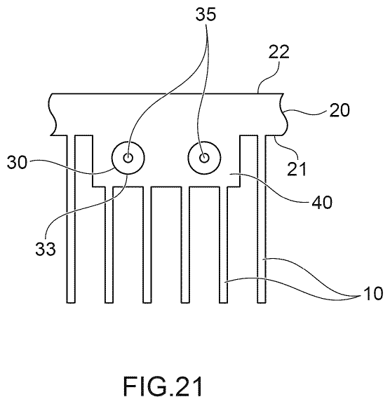

Next, a heat sink according to a tenth embodiment of the present disclosure will be described using the drawings. The heat sink according to the tenth embodiment has main components in common with the heat sinks according to the first to ninth embodiments, and therefore the same components as those in the heat sinks according to the first to ninth embodiments will be described using the same reference signs. Note that FIG. 20 is an explanatory view of an injection tube used in a heat pipe provided in the heat sink according to the tenth embodiment of the present disclosure. FIG. 21 is a side view explaining the injection tube used in the heat pipe provided in the heat sink according to the tenth embodiment of the present disclosure.

In the heat sink 9 according to the ninth embodiment, the container 33 of the heat pipe 30 has the one end portion extended in the thickness direction of the base portion 20, and the end surface of the one end portion of the container 33 is exposed from the second surface 22. Instead of this, as shown in FIGS. 20 and 21, in a heat sink 80 according to the tenth embodiment, a container 33 of a heat pipe 30 extends substantially linearly along an extending direction of a base portion 20, and an end surface of one end portion of the container 33 is exposed from a peripheral edge portion 23 of the heat sink 80. A sealed injection tube 35 extends in a parallel direction to an extending direction of the second surface 22 from the end surface of the one end portion of the container 33, and the entire sealed injection tube 35 protrudes from the peripheral edge portion 23 of the heat sink 80.

As above, the sealed injection tube 35 may be in an aspect in which the sealed injection tube 35 is provided in an outward direction from the peripheral edge portion 23 of the heat sink 80, and the entire sealed injection tube 35 is positioned outside of the peripheral edge portion 23. Since in the heat sink 80, the sealed injection tube 35 is likely to be exposed to an external environment, corrosion resistance is given to an outer surface of the injection tube 35 as necessary. As a unit configured to give corrosion resistance to the outer surface of the injection tube 35, coating the outer surface of the injection tube 35 with an organic solvent having corrosion resistance or the like is cited, for example.

Since in the heat sink 80, the base portion 20 and heat radiation fins 10 are also integrally molded, contact resistance between the base portion 20 and the heat radiation fins 10 is also suppressed, and thermal connectivity between the base portion 20 and the heat radiation fins 10 is improved. Accordingly, even when many heat-generating elements 100 having various heat generation amounts are thermally connected to the base portion 20 of the heat sink 80, heat transfer from the base portion 20 to the heat radiation fins 10 is also facilitated, in the heat sink 80. Furthermore, since in the heat sink 80, at least part of the heat pipe 30 is embedded, even when a shield portion is formed in the second surface 22 of the base portion 20, the heat sink 80 is also excellent in degree of freedom of arrangement of the heat pipes 30, and excellent in thermal connectivity of the heat pipes 30 in the heat sink 80. Accordingly, even when many heat-generating elements 100 having various heat generation amounts are thermally connected to the base portion 20 of the heat sink 80, heat is also diffused throughout the entire base portion 20 by the heat pipes 30, the entire base portion 20 is also made thermally uniform, and heat transfer from the base portion 20 is also uniformized in the entire heat radiation fins 10, in the heat sink 80. Accordingly, in the heat sink 80, thermal load in the entire heat radiation fins 10 is also uniformized to improve fin efficiency of the heat radiation fins 10. From the above, in the heat sink 80, heat radiation characteristics are also improved even when may heat-generating elements 100 having various heat generation amounts are thermally connected.

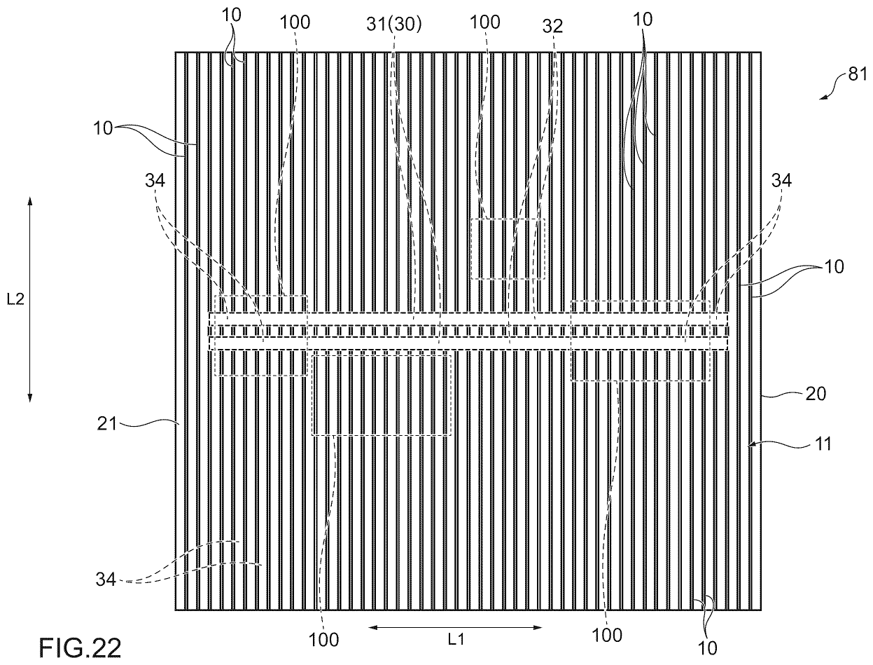

Next, a heat sink according to an eleventh embodiment of the present disclosure will be described using the drawings. The heat sink according to the eleventh embodiment has main components in common with the heat sinks according to the first to tenth embodiments, and therefore the same components as those in the heat sinks according to the first to tenth embodiments will be described using the same reference signs. Note that FIG. 22 is an explanatory view explaining arrangement of thermally conductive members of the heat sink according to the eleventh embodiment of the present disclosure from a plane direction.

In the heat sink 1 according to the first embodiment, the thermally conductive member 31 extends along the extending direction of the heat radiation fin 10, but instead of this, as shown in FIG. 22, in a heat sink 81 according to the eleventh embodiment, a thermally conductive member 31 in which a shape in a longitudinal direction is substantially linear extends at a predetermined angle with respect to an extending direction of a heat radiation fin 10. Accordingly, in the heat sink 81, the thermally conductive member 31 does not extend in a parallel direction to the extending direction of the heat radiation fin 10.

The angle with respect to the extending direction of the heat radiation fin 10, of the thermally conductive member 31 is not particularly limited, and in the heat sink 81, the thermally conductive member 31 extends along a substantially orthogonal direction to the extending direction of the heat radiation fin 10. In the heat sink 81, as the thermally conductive member 31, a heat pipe 30 is also cited, for example. In the heat sink 81, a plurality of heat pipes 30, 30, 30 . . . are arranged in parallel along the extending direction of the heat radiation fins 10.

As above, in the heat sink of the present disclosure, arrangement of the thermally conductive members 31 for making the entire base portion 20 thermally uniform can be appropriately selected according to the position of the heat-generating element 100, or the like.

Since in the heat sink 81, the base portion 20 and the heat radiation fins 10 are also integrally molded, contact resistance between the base portion 20 and the heat radiation fins 10 is suppressed, and thermal connectivity between the base portion 20 and the heat radiation fins 10 is also improved. Accordingly, even when many heat-generating elements 100 having various heat generation amounts are thermally connected to the base portion 20 of the heat sink 81, heat transfer from the base portion 20 to the heat radiation fins 10 is also facilitated in the heat sink 81. Furthermore, since in the heat sink 81, at least part of the heat pipe 30 is embedded, even when a shield portion is formed in a second surface 22 of the base portion 20, the heat sink 81 is also excellent in degree of freedom of arrangement of the heat pipes 30, and excellent in thermal connectivity of the heat pipes 30, in the heat sink 81. Accordingly, even when many heat-generating elements 100 having various heat generation amounts are thermally connected to the base portion 20 of the heat sink 81, heat is also diffused throughout the entire base portion 20 by the heat pipes 30, the entire base portion 20 is also made thermally uniform, and heat transfer from the base portion 20 is also uniformized in the entire heat radiation fins 10, in the heat sink 81. Accordingly, in the heat sink 81, thermal load in the entire heat radiation fins 10 is also equalized to improve fin efficiency of the heat radiation fins 10. From the above, in the heat sink 81, heat radiation characteristics are also improved even when many heat-generating elements 100 having various heat generation amounts are thermally connected.

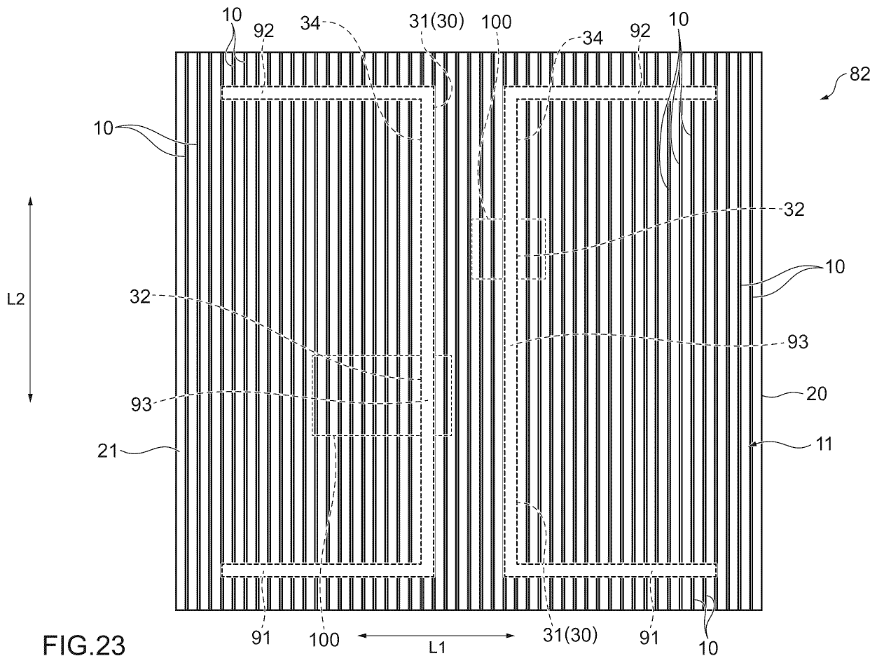

Next, a heat sink according to a twelfth embodiment of the present disclosure will be described using the drawings. The heat sink according to the twelfth embodiment has main components in common with the heat sinks according to the first to eleventh embodiments, and therefore the same components as those in the heat sinks according to the first to eleventh embodiments will be described using the same reference signs. Note that FIG. 23 is an explanatory view explaining arrangement of thermally conductive members of the heat sink according to the twelfth embodiment of the present disclosure from a plane direction.

In the heat sink 1 according to the first embodiment, the shape of the thermally conductive member 31 in the longitudinal direction is a substantially linear shape, and the thermally conductive member 31 extends along the extending direction of the heat radiation fin 10, but instead of this, as shown in FIG. 23, in a heat sink 82 according to the twelfth embodiment, a shape of a thermally conductive member 31 in a longitudinal direction is a shape having bent portions in plan view. As the shape having the bent portion, the shape may be a U-shape with right angles, an L-shape, a U-shape or the like in plan view and is not particularly limited, and is a U-shape with right angles in the heat sink 82 for convenience of explanation.

In the heat sink 82, the thermally conductive member 31 has a center portion 93 that extends substantially linearly along an extending direction of a heat radiation fin 10, and one end portion 91 and another end portion 92 that extend substantially linearly at a predetermined angle with respect to the extending direction of the heat radiation fin 10. Note that in the heat sink 82, the one end portion 91 and the other end portion 92 of the thermally conductive member 31 extend along a substantially orthogonal direction to the extending direction of the heat radiation fin 10. In the heat sink 82, for example, a heat pipe 30 is also cited as the thermally conductive member 31. Furthermore, in the heat sink 82, a plurality of heat pipes 30, 30, 30 . . . are arranged in an aspect in which the center portions 93 face each other.

As above, in the heat sink of the present disclosure, the shapes of the thermally conductive members 31 for making the entire base portion 20 thermally uniform can be appropriately selected, according to positions of the heat-generating elements 100, and or the like.

Since in the heat sink 82, the base portion 20 and the heat radiation fins 10 are also integrally molded, contact resistance between the base portion 20 and the heat radiation fins 10 is also suppressed, and thermal connectivity between the base portion 20 and the heat radiation fins 10 is also improved. Accordingly, even when many heat-generating elements 100 having various heat generation amounts are thermally connected to the base portion 20 of the heat sink 82, heat transfer from the base portion 20 to the heat radiation fins 10 is also facilitated, in the heat sink 82. Furthermore, since in the heat sink 82, at least part of the heat pipes 30 is also embedded, even when a shield portion is formed in the second surface 22 of the base portion 20, the heat sink 82 is also excellent in degree of freedom of arrangement of the heat pipes 30 and also excellent in thermal connectivity of the heat pipes 30 in the heat sink 82. Accordingly, even when many heat-generating elements 100 having various heat generation amounts are thermally connected to the base portion 20 of the heat sink 82, heat is also diffused throughout the entire base portion 20 by the heat pipes 30, the entire base portion 20 is also made thermally uniform, and heat transfer from the base portion 20 is also uniformized in the entire heat radiation fins 10, in the heat sink 82. Accordingly, in the heat sink 82, thermal load in the entire heat radiation fins 10 is also equalized to improve fin efficiency of the heat radiation fins 10. From the above, even when many heat-generating elements 100 having various heat generation amounts are thermally connected, heat radiation characteristics are also improved in the heat sink 82.

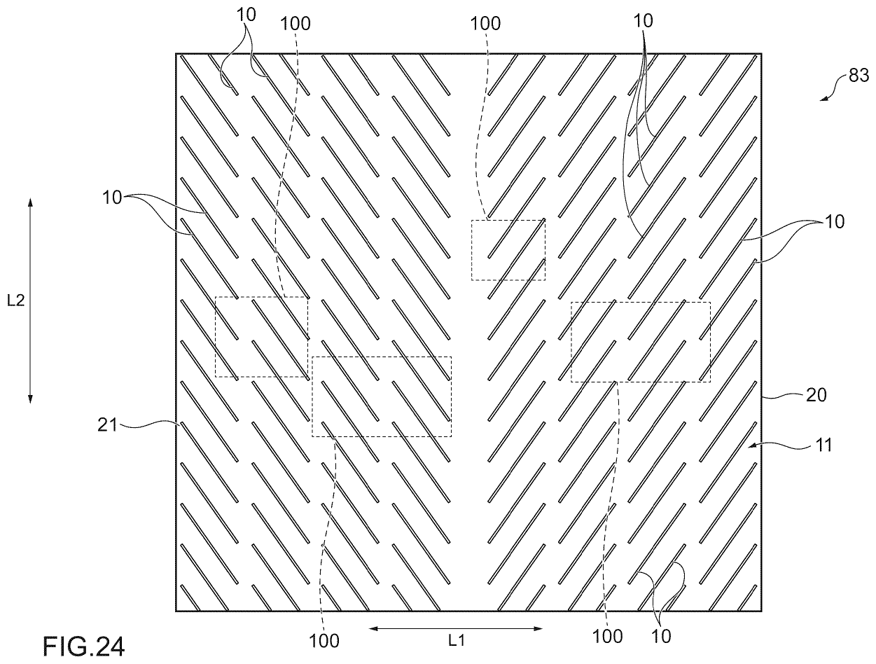

Next, a heat sink according to a thirteenth embodiment of the present disclosure will be described using the drawings. The heat sink according to the thirteenth embodiment has main components in common with the heat sinks according to the first to twelfth embodiments, and therefore the same components as those in the heat sinks according to the first to twelfth embodiments will be described using the same reference signs. Note that FIG. 24 is an explanatory view explaining arrangement of heat radiation fins of the heat sink according to the thirteenth embodiment of the present disclosure from a plane direction. Furthermore, in FIG. 24, for convenience of explanation of the arrangement of the heat radiation fins, illustration of thermally conductive members is omitted.

In the heat sink 1 according to the first embodiment, the respective heat radiation fins 10 extend in the substantially parallel direction to the second direction L2 of the base portion 20, and extend in the substantially orthogonal direction to the first direction L1, but instead of this, as shown in FIG. 24, in a heat sink 83 according to the thirteenth embodiment, respective heat radiation fins 10 extend in an oblique direction with respect to a second direction L2 of a base portion 20, and in an oblique direction with respect to a first direction L1. In the heat sink 83, the respective heat radiation fins 10 extend substantially linearly. In the heat sink 83, a plurality of heat radiation fins 10, 10, 10 . . . are arranged in parallel at predetermined intervals, on a first surface 21 of the base portion 20. Also, the plurality of heat radiation fins 10, 10, 10 . . . are arranged in parallel at substantially equal intervals along the second direction L2. Also, the plurality of heat radiation fins 10, 10, 10 . . . are arranged in parallel along the first direction L1.

As shown in FIG. 24, in the heat sink 83, the respective heat radiation fins 10 are arranged to extend to an upper part of the drawing (for example, extend from below to above in the gravity direction) as progress to an outward direction of the base portion 20. Specifically, in FIG. 24, the heat radiation fins 10 arranged on a left side of the base portion 20 are arranged to extend to the upper part of the drawing (for example, extend from below to above in the gravity direction) as progress to an outward direction (leftward direction in FIG. 24) of the base portion 20. Furthermore, the heat radiation fins 10 arranged on a right side of the base portion 20 are arranged to extend to the upper part of the drawing (extend from below to above in the gravity direction, for example) as progress to the outward direction (rightward direction in FIG. 24) of the base portion 20.

An angle of the heat radiation fin 10 in the extending direction with respect to the first direction L1 of the base portion 20 is not particularly limited, and, for example, a range of 40° to 70° is cited.

For example, when cooling air is supplied from below to above in the gravity direction along the second direction L2, the cooling air flows on the first surface 21 of the base portion 20 to the outward direction in the first direction L1 of the base portion 20, in the heat sink 83.

As above, in the heat sink of the present disclosure, in order to adjust the flow direction of the cooling air on the first surface 21 of the base portion 20, the extending direction of the heat radiation fins 10 provided upright on the first surface 21 can be appropriately selected.

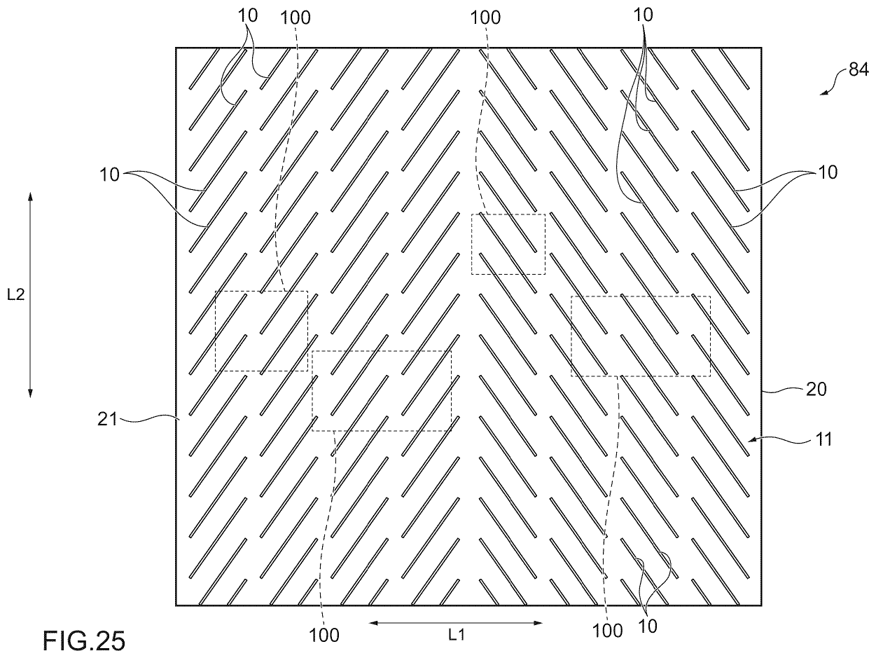

Next, a heat sink according to a fourteenth embodiment of the present disclosure will be described using the drawings. The heat sink according to the fourteenth embodiment has main components in common with the heat sinks according to the first to thirteenth embodiments, and therefore the same components as those in the heat sinks according to the first to thirteenth embodiments will be described using the same reference signs. Note that FIG. 25 is an explanatory view explaining arrangement of heat radiation fins of the heat sink according to the fourteenth embodiment of the present disclosure from a plane direction. Furthermore, in FIG. 25, for convenience of explanation of the arrangement of the heat radiation fins, illustration of thermally conductive members is omitted.

In the heat sink 83 according to the thirteenth embodiment, the respective heat radiation fins 10 are arranged to extend to the upper part of the drawing (for example, extend from below to above in the gravity direction) as progress to the outward direction of the base portion 20, but instead of this, as shown in FIG. 25, in a heat sink 84 according to the fourteenth embodiment of the present disclosure, respective heat radiation fins 10 are arranged to extend to a lower part of the drawing (for example, extend from above to below in the gravity direction) as progress to an outward direction of a base portion 20. From the above, in the heat sink 84, the respective heat radiation fins 10 extend in an oblique direction with respect to a second direction L2 of the base portion 20, and in an oblique direction with respect to a first direction L1, as in the heat sink 83 according to the above-described thirteenth embodiment.

Specifically, in FIG. 25, the heat radiation fins 10 arranged on a left side of the base portion 20 are arranged to extend to a lower part of the drawing (for example, extend from above to below in the gravity direction) as progress to the outward direction (leftward direction in FIG. 25) of the base portion 20. Furthermore, the heat radiation fins 10 arranged on a right side of the base portion 20 are arranged to extend to the lower part of the drawing (for example, extend from above to below in the gravity direction) as progress to the outward direction (rightward direction in FIG. 25) of the base portion 20.

An angle of the heat radiation fin 10 in the extending direction with respect to the first direction L1 of the base portion 20 is not particularly limited, and for example, a range of 40° to 70° is cited.

For example, when cooling air is supplied from below to above in the gravity direction along the second direction L2, the cooling air flows on a first surface 21 of the base portion 20 to an inward direction in the first direction L1 of the base portion 20, in the heat sink 84.

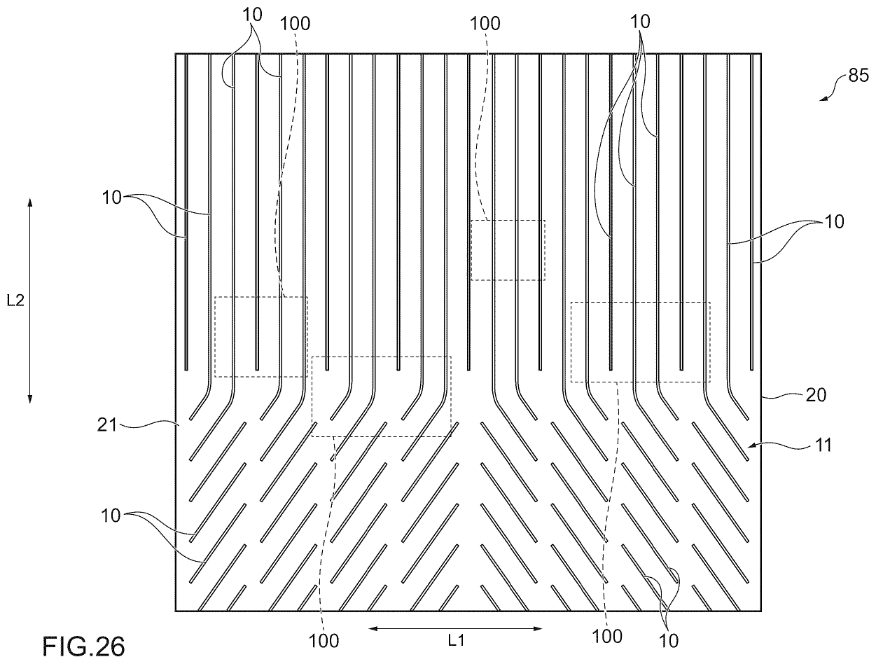

Next, a heat sink according to a fifteenth embodiment of the present disclosure will be described using the drawings. The heat sink according to the fifteenth embodiment has main components in common with the heat sinks according to the first to fourteenth embodiments, and therefore the same components as those in the heat sinks according to the first to fourteenth embodiments will be described using the same reference signs. Note that FIG. 26 is an explanatory view explaining arrangement of heat radiation fins of the heat sink according to the fifteenth embodiment of the present disclosure from a plane direction. Furthermore, in FIG. 26, for convenience of explanation of the arrangement of the heat radiation fins, illustration of thermally conductive members is omitted.

In the heat sink 1 according to the first embodiment, the respective heat radiation fins 10 extend in the substantially parallel direction to the second direction L2 of the base portion 20, and extend in the substantially orthogonal direction to the first direction L1, but instead of this, as shown in FIG. 26, a heat sink 85 according to the fifteenth embodiment has oblique heat radiation fins 10 extending in an oblique direction with respect to a second direction L2 of a base portion 20, and parallel heat radiation fins 10 extending in a substantially parallel direction with respect to the second direction L2 of the base portion 20. Furthermore, the heat sink 85 has composite type heat radiation fins 10 each having a parallel site extending in a substantially parallel direction with respect to the second direction L2 of the base portion 20, and an oblique site extending in an oblique direction with respect to the second direction L2 of the base portion 20.

In the heat sink 85, in FIG. 26, the heat radiation fins 10 arranged on an upper side (upper part in the gravity direction, for example) of the base portion 20 are the parallel heat radiation fins 10, and the heat radiation fins 10 arranged on a lower side (lower part in the gravity direction, for example) of the base portion 20 are the oblique heat radiation fins 10. Furthermore, in each of the composite type heat radiation fins 10, a parallel site is positioned on the upper side (upper part in the gravity direction, for example) of the base portion 20, and an oblique site is positioned on the lower side (lower part in the gravity direction, for example) of the base portion 20. A plurality of parallel heat radiation fins 10, 10, 10 . . . and parallel sites of a plurality of composite type heat radiation fins 10, 10, 10 . . . are arranged in parallel at predetermined intervals. Furthermore, a plurality of oblique heat radiation fins 10, 10, 10 . . . and oblique sites of the plurality of composite type heat radiation fins 10, 10, 10 . . . are arranged in parallel at predetermined intervals.

In the heat sink 85, the oblique heat radiation fins 10 and the oblique sites of the composite type heat radiation fins 10 that are arranged on a left side of the base portion 20 are arranged to extend to a lower part of the drawing (for example, extend from above to below in the gravity direction) as progress to an outward direction (leftward direction in FIG. 26) of the base portion 20. Furthermore, the oblique heat radiation fins 10 and the oblique sites of the composite type heat radiation fins 10 that are arranged on a right side of the base portion 20 are arranged to extend to a lower part of the drawing (for example, extend from above to below in the gravity direction) as progress to the outward direction (rightward direction in FIG. 26) of the base portion 20.

An angle of the oblique heat radiation fin 10 and the oblique site of the composite type heat radiation fin 10 in the extending direction with respect to a first direction L1 of the base portion 20 is not particularly limited, and for example, a range of 40° to 70° is cited.

For example, when cooling air is supplied from below to above in the gravity direction along the second direction L2, the cooling air flows on a first surface 21 of the base portion 20 to an inward direction in the first direction L1 of the base portion 20 on the lower side (lower part in the gravity direction) of the base portion 20, and on the upper side (upper part in the gravity direction) of the base portion 20, the cooling air flows on the first surface 21 of the base portion 20 along the second direction L2, in the heat sink 85.

Since in the heat sinks 83, 84 and 85, the base portion 20 and the heat radiation fins 10 are also integrally molded, contact resistance between the base portion 20 and the heat radiation fins 10 is also suppressed, and thermal connectivity between the base portion 20 and the heat radiation fins 10 is also improved. Accordingly, even when many heat-generating elements 100 having various heat generation amounts are thermally connected to the base portions 20 of the heat sinks 83, 84 and 85, heat transfer from the base portions 20 to the heat radiation fins 10 is also facilitated, in the heat sinks 83, 84 and 85. Furthermore, since in the heat sinks 83, 84 and 85, at least parts of thermally conductive members (not shown) are also embedded, even when shield portions are formed on the second surfaces 22 of the base portions 20, the heat sinks 83, 84 and 85 are also excellent in degree of freedom of arrangement of the thermally conductive members and excellent in thermal connectivity of the thermally conductive members in the heat sinks 83, 84 and 85. Accordingly, even when many heat-generating elements 100 having various heat generation amounts are thermally connected to the base portions 20 of the heat sinks 83, 84 and 85, heat is also diffused throughout the entire base portions 20 by the thermally conductive members, the entire base portions 20 are also made thermally uniform, and heat transfer from the base portions 20 is also uniformized in the entire heat radiation fins 10, in the heat sinks 83, 84 and 85. Accordingly, in the heat sinks 83, 84 and 85, thermal load in the entire heat radiation fins 10 is also equalized to improve fin efficiency of the heat radiation fins 10. From the above, even when many heat-generating elements 100 having various heat generation amounts are thermally connected, heat radiation characteristics are also improved in the heat sinks 83, 84 and 85.

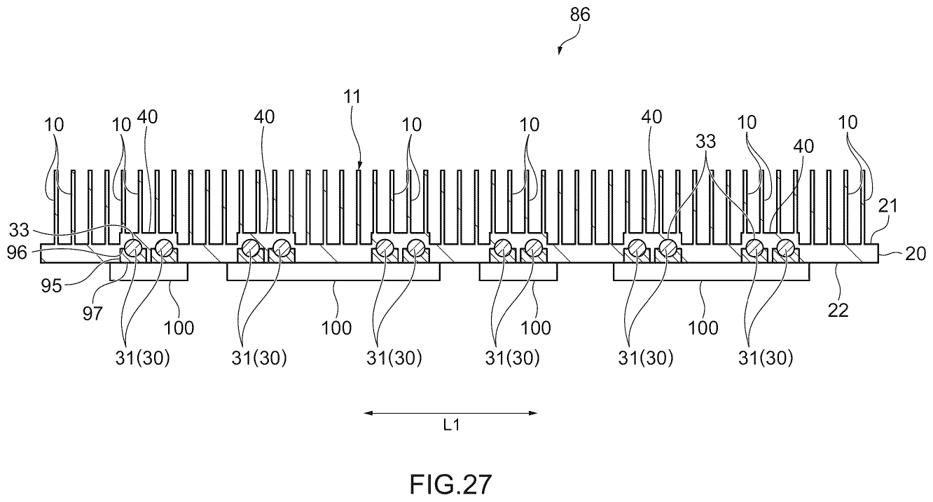

Next, a heat sink according to a sixteenth embodiment of the present disclosure will be described using the drawings. The heat sink according to the sixteenth embodiment has main components in common with the heat sinks according to the first to fifteenth embodiments, and therefore the same components as those in the heat sinks according to the first to fifteenth embodiments will be described using the same reference signs. Note that FIG. 27 is a sectional side view of the heat sink according to the sixteenth embodiment of the present disclosure.

In the heat sink 1 according to the first embodiment, the entire thermally conductive member 31 is embedded in the heat sink 1, and the thermally conductive member 31 is thermally connected to the heat-generating element 100 via the base portion 20. Instead of this, as shown in FIG. 27, in a heat sink 86 according to the sixteenth embodiment, a thermally conductive member 31 is thermally connected to a heat-generating element 100 via a block-shaped member 95 that is a separate body from a base portion 20. In the heat sink 86, the block-shaped member 95 is connected to a site facing the heat-generating element 100, in the thermally conductive member 31, and further, the block-shaped member 95 is thermally connected to the heat-generating element 100. From the above, in the heat sink 86, heat of the heat-generating element 100 is transferred from the heat-generating element 100 to the block-shaped member 95, and the heat transferred from the heat-generating element 100 to the block-shaped member 95 is transferred to the thermally conductive member 31 from the block-shaped member 95.

In the heat sink 86, in the thermally conductive member 31, a portion to which the block-shaped member 95 is not connected is also embedded in the heat sink 86 by insert-casting. Accordingly, as for the portion to which the block-shaped member 95 is not connected, in the thermally conductive member 31, an entire outer peripheral surface of the thermally conductive member 31 is embedded in the heat sink 86 by insert-casting. Furthermore, the block-shaped member 95 is connected to a site facing the heat-generating element 100, in the thermally conductive member 31, and thereby the entire thermally conductive member 31 is embedded in the heat sink 86. The block-shaped member 95 is fitted into a recessed part 96 provided in a second surface 22 of the base portion 20, and thereby thermally connected to the thermally conductive member 31. Further, the block-shaped member 95 may be joined to the thermally conductive member 31 as necessary. As a joining method, for example, brazing, soldering and the like are cited.

In the block-shaped member 95, the site facing the heat-generating element 100 is positioned on a same plane as the second surface 22 of the base portion 20. Accordingly, in the block-shaped member 95, an exposure portion 97 from the base portion 20, which is the site facing the heat-generating element 100, is a plane portion positioned on the same plane as the second surface 22. The exposure portion 97 of the block-shaped member 95 contacts the heat-generating element 100, and the block-shaped member 95 is thermally connected to the heat-generating element 100. Note that the block-shaped member 95 may have a protruding part that is protruded along a thickness direction of the base portion 20 from the second surface 22 of the base portion 20. In other words, in the block-shaped member 95, the site facing the heat-generating element 100 may protrude from the second surface 22 of the base portion 20, the protruding part of the block-shaped member 95 may contact the heat-generating element 100, and the block-shaped member 95 may be thermally connected to the heat-generating element 100.

As the block-shaped member 95, a solid member having thermal conductivity is cited. Furthermore, as a material of the block-shaped member 95, for example, metals such as copper, and copper alloy are cited. In the heat sink 86, as the thermally conductive member 31, a heat pipe 30 is cited as in the above-described respective embodiments.

Since in the heat sink 86, the base portion 20 and heat radiation fins 10 are integrally molded, contact resistance between the base portion 20 and the heat radiation fins 10 is suppressed, and thermal connectivity between the base portion 20 and the heat radiation fins 10 is improved. Accordingly, even when many heat-generating elements 100 having various heat generation amounts are thermally connected to the base portion 20 of the heat sink 86, heat transfer from the base portion 20 to the heat radiation fins 10 is also facilitated, in the heat sink 86. Furthermore, since in the heat sink 86, at least a part of each of the thermally conductive members 31 is also embedded, even when a shield portion is formed in the second surface 22 of the base portion 20, the heat sink 86 is also excellent in degree of freedom of arrangement of the thermally conductive members 31, and excellent in thermal connectivity of the thermally conductive members 31 in the heat sink 86. Accordingly, even when many heat-generating elements 100 having various heat generation amounts are thermally connected to the base portion 20 of the heat sink 86, heat is also diffused throughout the entire base portion 20 by the thermally conductive members 31, the entire base portion 20 is also made thermally uniform, and heat transfer from the base portion 20 is also uniformized in the entire heat radiation fins 10, in the heat sink 86. Accordingly, in the heat sink 86, thermal load in the entire heat radiation fins 10 is also equalized to improve fin efficiency of the heat radiation fins 10. From the above, in the heat sink 86, heat radiation characteristics are also improved even when many heat-generating elements 100 having various heat generation amounts are thermally connected.

Next, other embodiments of the heat sink of the present disclosure will be described. In the heat sinks of the above-described respective embodiments, the heat pipes or vapor chambers that are the heat transport members are used as the thermally conductive members, but the thermally conductive members are not particularly limited as long as they are members having thermal conductivity, and instead of the heat transport members, rod-shaped members or plate-shaped members that are solid and made of metal (for example, made of copper), or rod-shaped members or plate-shaped members that are solid and made of graphite may be used. Furthermore, in the heat sink of each of the above-described embodiments, the heat pipes are embedded in the block portions, but instead of this, the entire heat pipes may be embedded in the base portion.

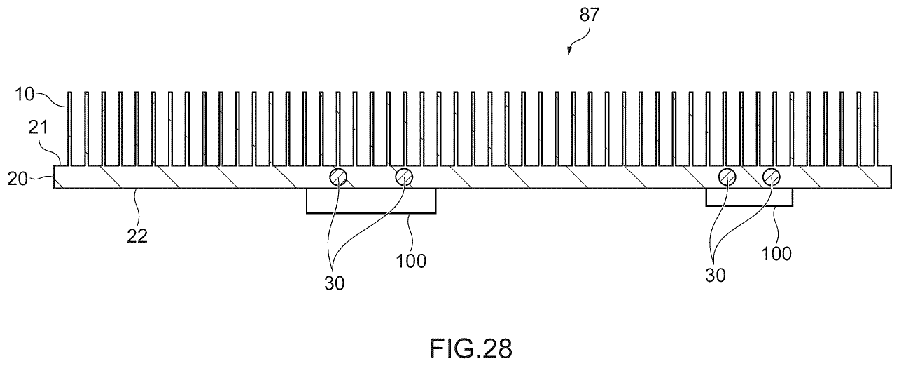

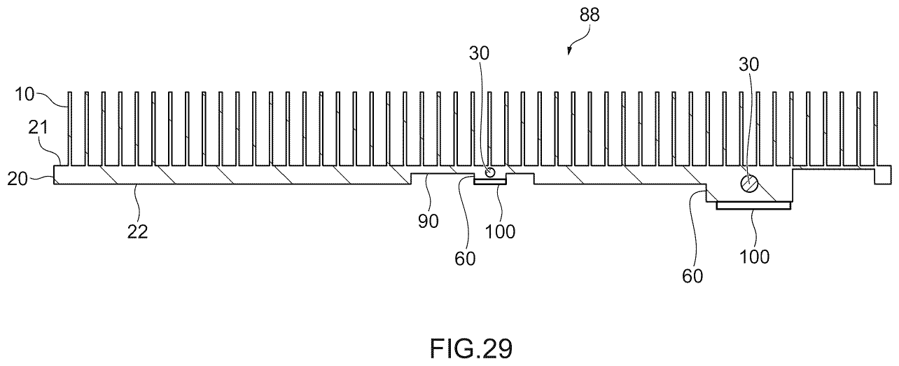

For example, as shown in FIG. 28, a heat sink 87 in which no block portion is provided, and entire heat pipes 30 are embedded in a base portion 20 may be adopted. The heat sink 87 has a structure in which a diameter of each of the heat pipes 30 is smaller than a thickness of the base portion 20. Furthermore, as shown in FIG. 29, a heat sink 88 may be adopted, in which block portions 60 that are protruding parts of a second surface 22, which are protruded in a thickness direction of a base portion 20 from the second surface 22 of the base portion 20 are provided on the second surface 22 and a recessed part 90 formed in the second surface 22, and the block portion 60 provided in the recessed part 90 does not protrude from the second surface 22. In the heat sink 88, heat pipes 30 are also embedded in the block portions 60. The recessed part 90 is a region where a thickness of the base portion 20 is reduced. The block portion 60 provided on the second surface 22 that is a region other than the recessed part 90 more protrudes in the thickness direction of the base portion 20 than the block portion 60 provided in the recessed part 90. Accordingly, even when a plurality of heat-generating elements 100 that are installed and have different heights are objects to be cooled of the heat sink 88, the heat sink 88 has excellent thermal connectivity to the plurality of heat-generating elements 100.

Furthermore, in the heat sink of each of the above-described embodiments, the shape of the base portion is a quadrangle in plan view (state of seen from a position facing the heat radiation fins), but the shape of the base portion can be appropriately selected according to the conditions of use of the heat sink, and the like, and may be a shape having a bent portion, a shape having a cutout portion and the like in plan view. Furthermore, in the heat sink of each of the above-described embodiments, the heat radiation fins extend substantially linearly from the one end to the other end in the second direction of the base portion, but the shape of the base portion in the second direction is not particularly limited, and instead of this, it may be a shape having a bent portion.

Furthermore, in the heat sink of the first embodiment, the dimension in the perpendicular direction of the sealed injection tube is the dimension smaller than the thickness of the base portion, but instead of this, the heat sink may be in an aspect in which the dimension of the sealed injection tube in the perpendicular direction is a dimension larger than the thickness of the base portion, and the tip portion of the sealed injection tube protrudes from the second surface of the base portion.

Since the heat sink of the present disclosure is excellent in thermal connectivity of the base portion and the heat radiation fins, and excellent in degree of freedom of arrangement of the thermally conductive members, further can prevent rainwater, dust and the like from entering between the base portion and the heat radiation fins, and has excellent durability, the heat sink of the present disclosure is particularly of high utility value in the field of cooling heat-generating elements mounted in communication devices installed outdoors in mobile phone base stations and the like.

What is claimed is:

1. A heat sink comprising:
a base portion having a first surface and a second surface facing the first surface, in which a heat-generating element is to be thermally connected to the second surface; and
heat radiation fins provided upright on the first surface of the base portion,
wherein the base portion and the heat radiation fins are integrally molded, and
at least a part of a thermally conductive member is embedded in the heat sink.

2. The heat sink according to claim 1, comprising a block portion extended in an extending direction of the base portion, wherein the thermally conductive member is embedded in the block portion.

3. The heat sink according to claim 1, wherein the thermally conductive member is embedded in the base portion.

4. The heat sink according to claim 2, wherein the block portion is a protruding part of the first surface, which is protruded in a thickness direction of the base portion from the first surface of the base portion.

5. The heat sink according to claim 2, wherein the block portion is a protruding part of the second surface, which is protruded in a thickness direction of the base portion from the second surface of the base portion.

6. The heat sink according to claim 2, wherein the heat radiation fins each have a tip portion in a height direction of the heat radiation fins and a basal portion that is a rise start portion from the base portion, and the block portion is provided in a middle portion between the tip portion and the basal portion of each of the heat radiation fins.

7. The heat sink according to claim 1, wherein the thermally conductive member has a heat receiving portion to be thermally connected to the heat-generating element.

8. The heat sink according to claim 1, wherein the entire thermally conductive member is embedded in the heat sink.

9. The heat sink according to claim 1, wherein at least a partial region of the thermally conductive member has an exposed portion exposed from the second surface of the base portion, and the exposed portion is to be directly in contact with the heat-generating element.

10. The heat sink according to claim 5, wherein at least a partial region of the thermally conductive member has an exposed portion exposed from the protruding part of the second surface, and the exposed portion is to be directly in contact with the heat-generating element.

11. The heat sink according to claim 1, wherein the thermally conductive member extends along an extending direction of the base portion.

12. The heat sink according to claim 9, wherein the thermally conductive member has a step portion bent in a thickness direction of the base portion, and the exposed portion is formed by the step portion.

13. The heat sink according to claim 9, wherein the thermally conductive member has a protrusion portion protruded in a thickness direction of the base portion, and the exposed portion is formed by the protrusion portion.

14. The heat sink according to claim 1, wherein the thermally conductive member is a heat pipe or a vapor chamber.

15. The heat sink according to claim 1, wherein the heat sink is a cast member, and the thermally conductive member is embedded in the heat sink by insert-casting.

16. The heat sink according to claim 14, wherein a sealed injection tube that is used to inject a working fluid into an inside of the heat pipe or the vapor chamber is provided in an inward direction from a peripheral edge portion of the heat sink.

17. The heat sink according to claim 14, wherein the heat pipe is a flat type heat pipe that is flattened.

18. The heat sink according to claim 1, comprising a block portion extended in an extending direction of the base portion, in which at least a part of the thermally conductive member is embedded in the block portion,
wherein the block portion is a protruding part of the first surface, which is protruded in a thickness direction of the base portion from the first surface of the base portion, and
on the block portion, the heat radiation fins that are lower than the heat radiation fins provided upright on the first surface other than the block portion are provided upright.

19. The heat sink according to claim 1, wherein a shape of the thermally conductive member in a longitudinal direction is a shape having a bent portion in plan view.

20. The heat sink according to claim 1, wherein the base portion has a first direction and a second direction orthogonal to the first direction, and the heat radiation fins extend in an oblique direction with respect to the second direction of the base portion, and in an oblique direction with respect to the first direction.
